(19) United States
(12) Patent Application Publication
(10) Pub. No.: US 2025/0241122 A1
(43) Pub. Date: Jul. 24, 2025

(54) LIGHT-EMITTING DEVICE, DISPLAY PANEL AND DISPLAY APPARATUS

(71) Applicant: BOE Technology Group Co., Ltd., Beijing (CN)

(72) Inventors: Rongrong GAO, Beijing (CN); Dan WANG, Beijing (CN); Lei CHEN, Beijing (CN); Dongxu ZHANG, Beijing (CN); Juncong LI, Beijing (CN)

(21) Appl. No.: 18/686,576

(22) PCT Filed: Dec. 21, 2022
(86) PCT No.: PCT/CN2022/140806

§ 371 Date: Feb. 26, 2024

(51) Int. Cl. H10K 50/19; H10K 50/13; H10K 85/30; H10K 85/60; H10K 101/30

(52) U.S. Cl. CPC H10K 50/19; H10K 50/13; H10K 85/342; H10K 85/615; H10K 85/633; H10K 85/636; H10K 85/654; H10K 85/6572; H10K 85/6574; H10K 85/6576; H10K 2101/30

(57) ABSTRACT

Provided are a light emitting device, a display panel and a display apparatus. The light-emitting device includes: an anode and a cathode arranged oppositely, a light-emitting unit and a charge generation layer. The light-emitting unit is between the anode and the cathode, wherein the light-emitting unit includes: a first light-emitting unit and a second light-emitting unit which are stacked sequentially along a first direction. The charge generation layer is between the first light-emitting unit and the second light-emitting unit. The charge generation layer includes: a first charge generation layer and a second charge generation layer which are stacked sequentially along the first direction. The first charge generation layer includes a first type compound, the second charge generation layer includes a second type compound and a third type compound, and the first direction is the direction from the anode to the cathode.

### TECHNICAL FIELD

The present disclosure relates to the technical field of display and lighting, and in particular, to a light-emitting device, a display panel and a display apparatus.

### BACKGROUND

OLED (Organic Light-Emitting Diode) has a feature of self-luminous and does not need backlights, and the OLED panel is thin and lightweight. Meanwhile, the OLED further has advantages of wider viewing angle, larger contrast, faster response time, wider operating-temperature range and flexibility. In the field of organic semiconductor technology applications, the OLED technology has been successfully used in the commercial flat panel display and the lighting industry. Stacked OLEDs play a decisive role in the field of OLED display and lighting.

Compared with the traditional OLED, the luminous efficiency of the stacked OLED has been improved by some degree. The stacked OLEDs usually use a connecting layer to connect multiple organic light-emitting units in series to achieve the effect of increasing the current efficiency and the luminous brightness two or more times. The connecting layer between two stacked light-emitting units is referred to the charge generation layer (CGL). The performance of the charge generation layer will directly affect the optoelectronic performance of the entire device. Therefore, the material type of the charge generation layer and the parameter coordination relationship between the charge generation layer and other film layers inside the light-emitting device will affect the luminous efficiency and the service life of the light-emitting device.

However, existing stacked OLEDs still suffer from the low luminous efficiency or the short service life.

### SUMMARY

In view of the shortcomings of the prior art, the present disclosure proposes a light-emitting device, a display panel and a display apparatus to solve the technical problems of the low luminous efficiency or the short service life of the light-emitting device existing in the prior art.

According to the first aspect of the embodiments of the present disclosure, a light-emitting device is provided, which includes:
an anode and a cathode which are oppositely disposed;
a light-emitting unit between the anode and the cathode, where the light-emitting unit includes: a first light-emitting unit and a second light-emitting unit which are stacked along a first direction;
a charge generation layer between the first light-emitting unit and the second light-emitting unit. The charge generation layer includes: a first charge generation layer and a second charge generation layer stacked along the first direction.

The first charge generation layer includes a first type compound. The second charge generation layer includes a second type compound and a third type compound.

The first direction is from the anode to the cathode.

The first type compound has a structure shown in formula (I):

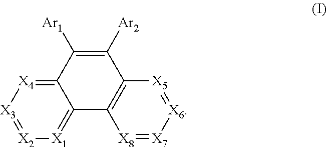

In the formula (I), X₁ to X₈ are the same or different, each of the X₁ to X₈ is independently selected from nitrogen or R₁, and the X₁ to X₈ include at least two nitrogen atoms; R1 is independently selected froma group consisting of hydrogen, deuterium, substituted C₁ to C₆₀ alkyl group, unsubstituted C₁ to C₆₀ alkyl group, substituted C₂ to C₆₀ alkenyl group, unsubstituted C₂ to C₆₀ alkenyl group, substituted C₂ to C₆₀ alkynyl group, unsubstituted C₂ to C₆₀ alkynyl group, substituted C₁ to C₆₀ alkoxy group, unsubstituted C₁ to C₆₀ alkoxy group, substituted C₃ to C₁₀ ring alkyl, unsubstituted C₃ to C₁₀ ring alkyl, substituted C₁ to C₁₀ heterocycloalkyl, unsubstituted C₁ to C₁₀ heterocycloalkyl, substituted C₃ to C₁₀ cycloalkenyl, unsubstituted C₃ to C₁₀ cycloalkenyl, substituted C₁ to C₁₀ heterocycloalkenyl, unsubstituted C₁ to C₁₀ heterocycloalkenyl, substituted C₆ to C₆₀ aryl group, unsubstituted C₆ to C₆₀ aryl group, substituted C₆ to C₆₀ aryloxy group, unsubstituted C₆ to C₆₀ aryloxy group, substituted C₆ to C₆₀ arylthio group, unsubstituted C₆ to C₆₀ arylthio group, substituted C₁ to C₆₀ heteroaryl group, unsubstituted C₁ to C₆₀ heteroaryl group, substituted monovalent non-aromatic condensed polycyclic group, unsubstituted monovalent non-aromatic condensed polycyclic group, substituted monovalent non-aromatic condensed heteropolycyclic group and unsubstituted monovalent non-aromatic condensed heteropolycyclic group. Ar₁ and Ar₂ are the same or different, each of the Ar₁ and Ar₂ is independently selected froma group consisting of: hydrogen, deuterium, tritium, halogen, cyano, nitro, C₆ to C₆₀ aryl, C₂ to C₆₀ heterocyclic group containing at least one heteroatom from O, N, S, Si and P, C₃ to C₆₀ aliphatic ring, C₆ to C₆₀ aromatic ring fused ring group, C₁ to C₅₀ alkyl group, C₂ to C₂₀ alkenyl group, C₂ to C₂₀ alkynyl group, C₁ to C₃₀ alkoxy group, C₆ to C₃₀ aryloxy group, C₃ to C₆₀ alkylsilyl group, C₁₈ to C₆₀ arylsilyl group and C₈ to C₆₀ alkylarylsilyl group.

The second type compound has a structure shown in formula (II):

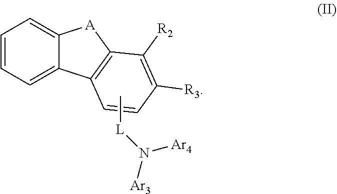

In the formula (II), A may indicate O, S, C, N, or Si. L indicates a direct bond, independently selected froma group consisting of: substituted phenyl group, unsubstituted phenyl group, substituted biphenyl, unsubstituted biphenyl, substituted terphenyl, unsubstituted terphenyl, substituted fluorenyl, unsubstituted fluorenyl, substituted adamantane group, unsubstituted adamantane group, substituted heteroaryl group, unsubstituted heteroaryl group. Substitution conditions of R₂ and R₃ are the same as the substitution condition of R₁. Ar₃ and Ar₄ are the same or different, each of the Ar₃ and Ar₄ is independently selected froma group consisting of: substituted phenyl group, unsubstituted phenyl group, substituted biphenyl group, unsubstituted biphenyl group, substituted naphthalene, unsubstituted naphthalene, substituted dibenzofuran, unsubstituted dibenzofuran, substituted carbazole, unsubstituted carbazole, substituted of fluorenyl group and unsubstituted of fluorenyl group.

The third type compound has a structure shown in formula (III):

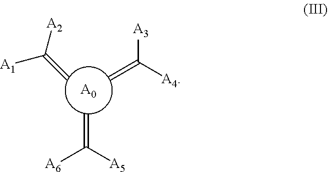

In the formula (III), each of the A₁ to A₆ is independently selected froma group consisting of: substituted or unsubstituted halogen, unsubstituted halogen, substituted or unsubstituted cyano group, unsubstituted cyano group, substituted or unsubstituted aldehyde group, unsubstituted aldehyde group, substituted or unsubstituted carbonyl group, unsubstituted carbonyl group, substituted or unsubstituted carboxyl group, unsubstituted carboxyl group, substituted or unsubstituted sulfonic acid group, unsubstituted sulfonic acid group, substituted or unsubstituted nitro group, unsubstituted nitro group, aryl group substituted by an electron-withdrawing group, and heteroaryl substituted by an electron-withdrawing group. A₀ may be a three-membered ring, a four-membered ring, a five-membered ring, or a six-membered ring.

According to the above embodiments, it can be seen that the charge generation layer in the light-emitting device provided by the present disclosure is composed of a second charge generation layer and a first charge generation layer. By optimizing the material type and the combination of the second charge generation layer or the first charge generation layer, the process of generation, transport and injection of holes and electrons can be optimized to ensure the effective injection and transport of the charges into the first light-emitting unit and the second light-emitting unit, thereby improving the luminous efficiency and the service life of the light-emitting device.

Specifically, where the heterocyclic compound represented by the formula (I) provided in this embodiment is used as a material of the first charge generation layer, the first charge generation layer has a lower LUMO energy level, which reduces the energy barrier at the interface between the first charge generation layer and the second charge generation layer, thereby inhibiting the degradation at the interface. In addition, the heterocyclic compound represented by the formula (I) has excellent electron transport ability, and based on the above structure, the heterocyclic compound can increase the electron mobility in the organic light-emitting device and prevent the reduction of the luminous efficiency of the light-emitting device under low current conditions. In addition, the heterocyclic compound represented by the formula (I) contains a large conjugate plane, when the heterocyclic compound is applied to a charge generation layer, the electron transmission characteristic can be effectively improved.

The compound represented by the formula (II) contains electron-rich arylamine and electron-rich dibenzo groups, and can form conjugate 1L bonds with adjacent groups, so that electrons in the molecule have high delocalization, thereby resulting in a higher mobility of this type of material to ensure the rapid transport of the carriers. Therefore, when the compound represented by the formula (II) is applied to the material of the second charge generation layer, the charge transfer efficiency of the charge generation layer can be improved.

The third type compound represented by the formula (III) contains a large number of electron-withdrawing groups, and the third type compound represented by the formula (III) has a lower LUMO energy level. After the second type compound represented by the formula (II) is mixed with the third type compound represented by the formula (III), the second type compound generates holes, and the electron-withdrawing group in the third type compound absorbs the HOMO unit of the second type compound, so that the mixture of the second type compounds and the third type compounds has a lower LUMO energy level, which contributes to generate the charges. The third type compound represented by the formula (III) contains a large number of electron-withdrawing groups, and the third type compound represented by the formula (III) has a lower LUMO energy level. After the second type compound represented by the formula (II) is mixed with the third type compound represented by the formula (III), the second type compound generates holes, and the electron-withdrawing group in the third type compound absorbs the HOMO unit of the second type compound, so that the mixture of the second type compounds and the third type compounds has a lower LUMO energy level, which contributes to generate the charges.

In an embodiment, the first type compound has a structure shown in any one of following formulas.

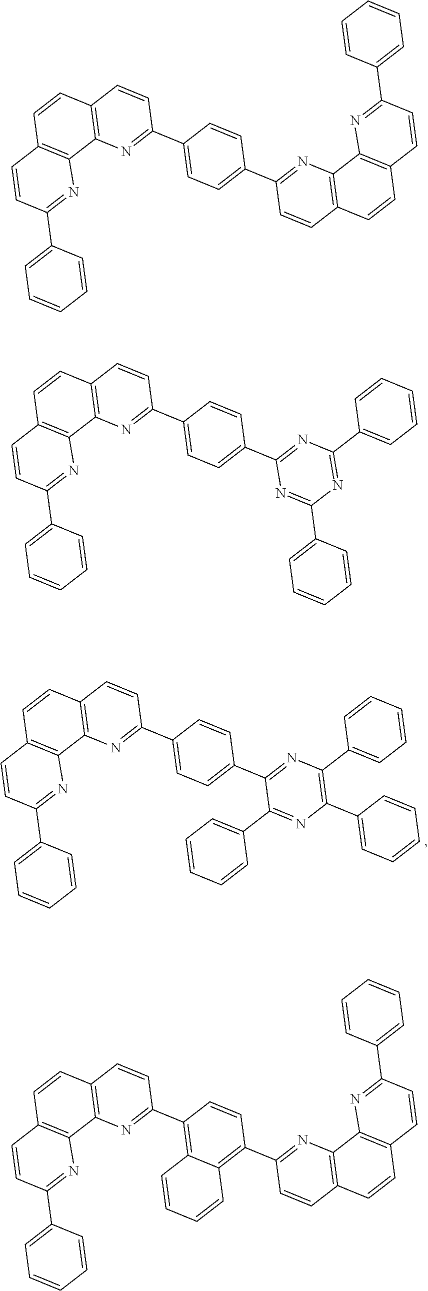 [SMILES: c1ccc(-c2ccc3ccc4ccc(-c5ccc(-c6ccc7ccc8ccc(-c9ccccc9)nc8c7n6)cc5)nc4c3n2)cc1 ; c1ccc(-c2ccc3ccc4ccc(-c5ccc(-c6nc(-c7ccccc7)nc(-c7ccccc7)n6)cc5)nc4c3n2)cc1 ; c1ccc(-c2ccc3ccc4ccc(-c5ccc(-c6nc(-c7ccccc7)c(-c7ccccc7)nc6-c6ccccc6)cc5)nc4c3n2)cc1 ; c1ccc(-c2ccc3ccc4ccc(-c5ccc(-c6ccc7ccc8ccc(-c9ccccc9)nc8c7n6)c6ccccc56)nc4c3n2)cc1]

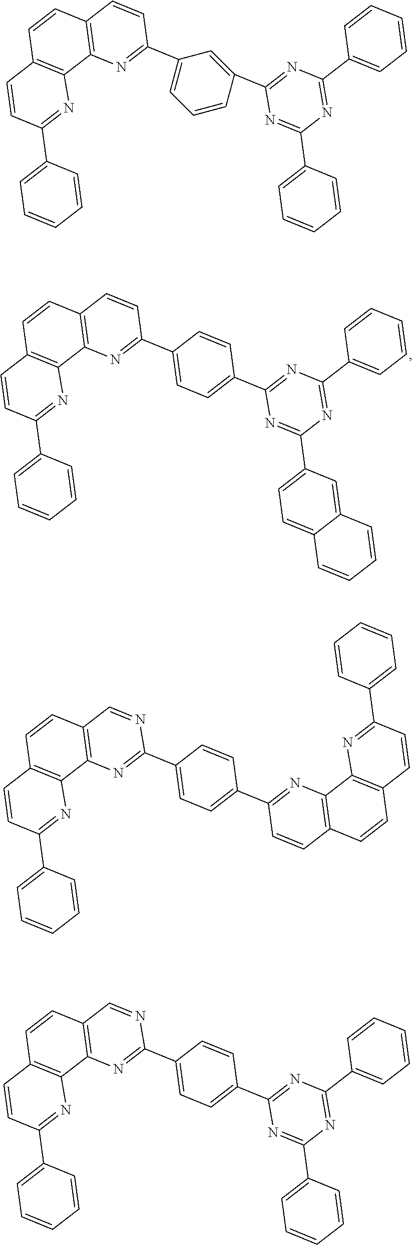

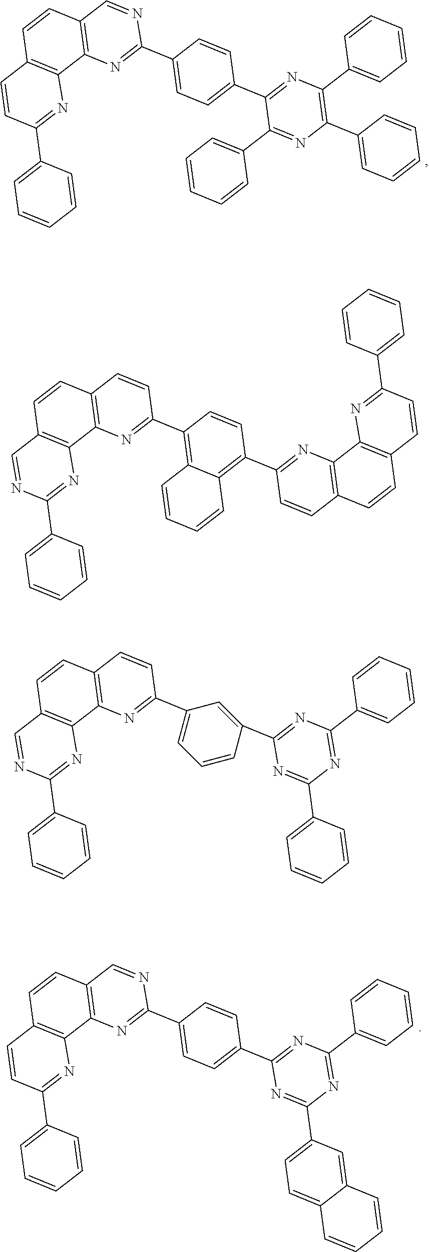 [SMILES: c1ccc(-c2ccc3ccc4cnc(-c5ccc(-c6nc(-c7ccccc7)c(-c7ccccc7)nc6-c6ccccc6)cc5)nc4c3n2)cc1 ; c1ccc(-c2ccc3ccc4ccc(-c5ccc(-c6ccc7ccc8cnc(-c9ccccc9)nc8c7n6)c6ccccc56)nc4c3n2)cc1 ; c1ccc(-c2nc(-c3ccccc3)nc(-c3cccc(-c4ccc5ccc6cnc(-c7ccccc7)nc6c5n4)c3)n2)cc1 ; c1ccc(-c2ccc3ccc4cnc(-c5ccc(-c6nc(-c7ccccc7)nc(-c7ccc8ccccc8c7)n6)cc5)nc4c3n2)cc1]

In an embodiment, the second type compound has a structure shown in any one of following formulas:

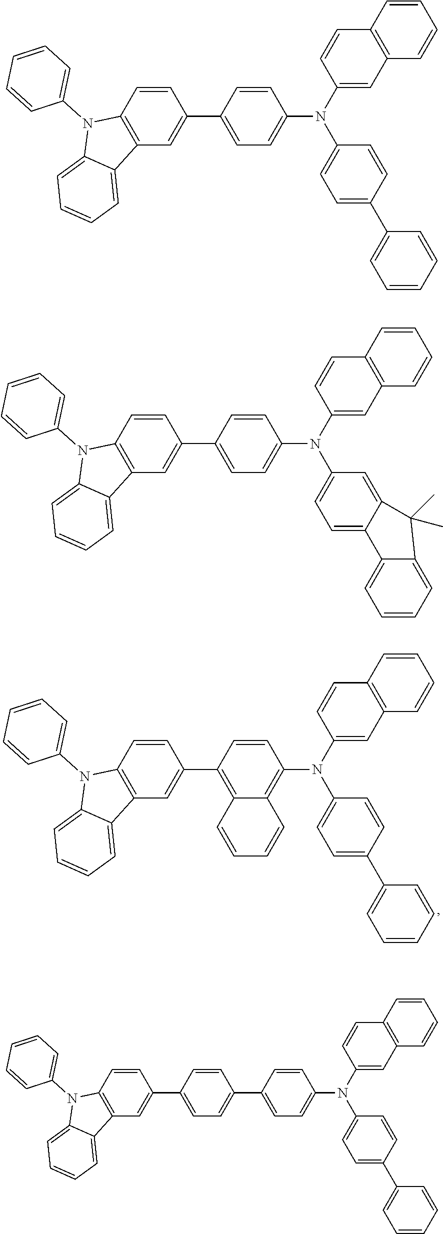

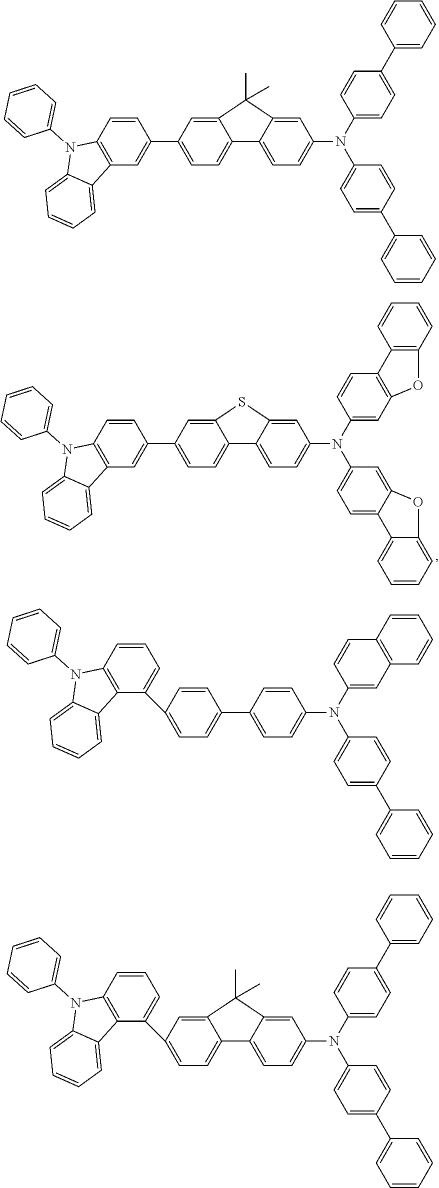

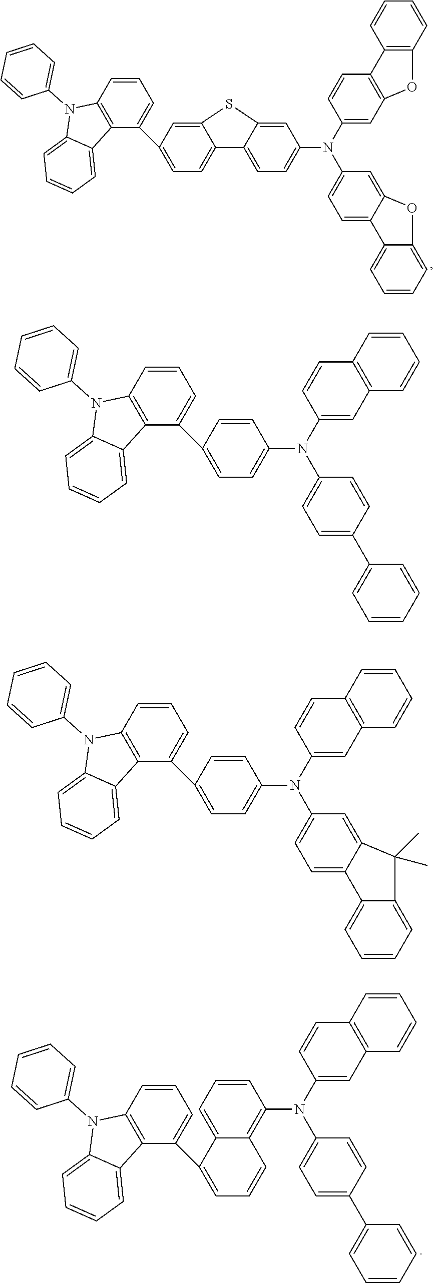

In an embodiment, the third type compound has a structure shown in any one of following formulas:

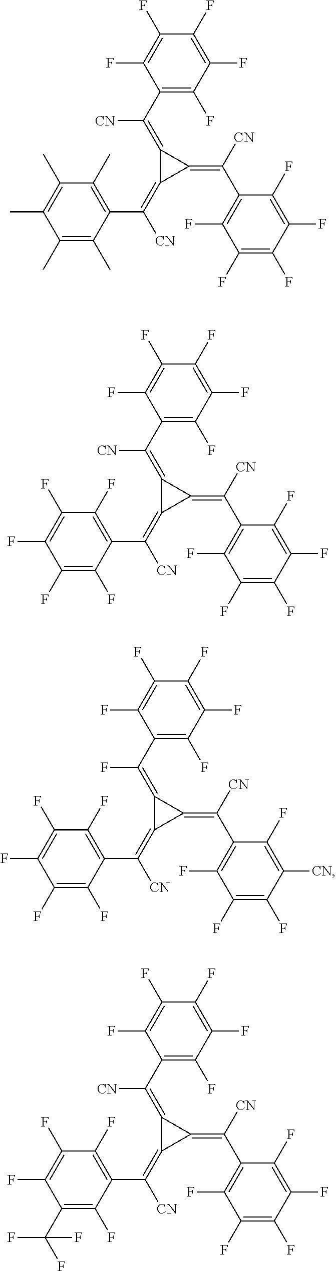

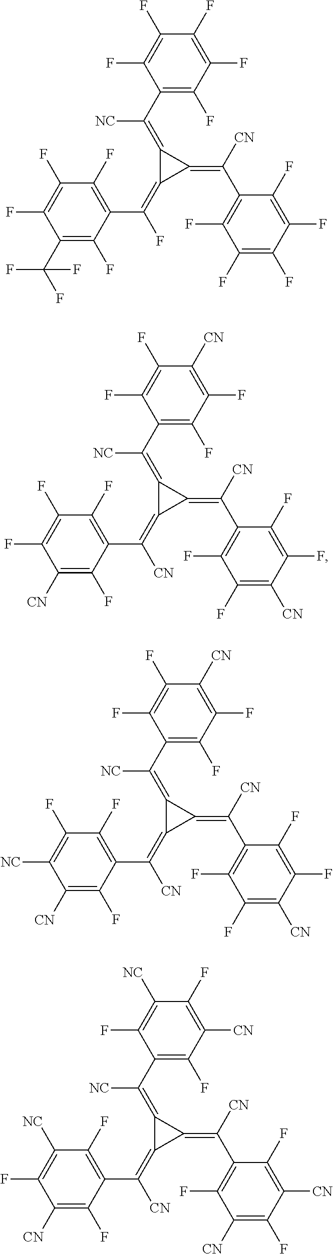

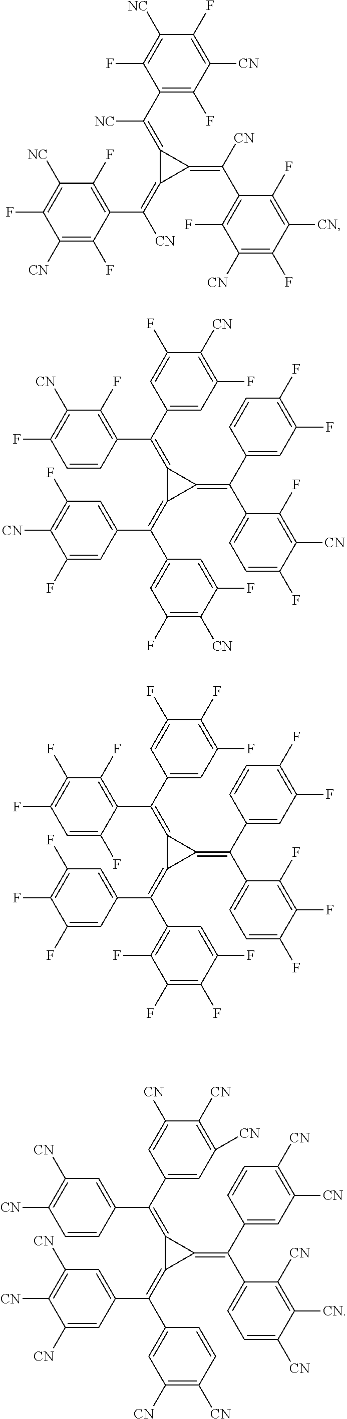

In an embodiment, the first light-emitting unit includes: a hole injection layer, a first hole transport layer, a first electron barrier layer, a first light-emitting layer and a first hole barrier layer that are stacked sequentially along the first direction. An absolute value of the difference between a Lowest Unoccupied Molecular Orbital (LUMO) energy level of the first charge generation layer and the LUMO energy level of the first hole barrier layer is less than or equal to 0.5 eV.

In an embodiment, the second light-emitting unit includes: a second hole transport layer, a second electron barrier layer, a second light emitting layer, a second hole barrier layer and an electron transport layer which are stacked along the first direction. An absolute value of the difference between a Highest Occupied Molecular Orbital (HOMO) energy level of the second charge generation layer and the HOMO energy level of the second hole transport layer is less than or equal to 0.3 eV.

In an embodiment, a dipole moment of the charge generation layer is greater than 4·10⁻¹⁸ esu·cm.

In an embodiment, an electron mobility of the first charge generation layer is greater than an electron mobility of the first hole barrier layer.

In an embodiment, a hole mobility of the second charge generation layer is greater than a hole mobility of the second hole transport layer.

In an embodiment, the ratio between the electron mobility of the first hole barrier layer and the electron mobility of the second hole barrier layer is greater than or equal to 0.1 and less than or equal to 10.

In an embodiment, the ratio between the hole mobility of the first hole transport layer and the hole mobility of the second hole transport layer is greater than or equal to 0.1 and less than or equal to 10.

In an embodiment, the light-emitting device has a first light-emitting region, a second light-emitting region, and a third light-emitting region that are arranged sequentially along a second direction, where the second direction is perpendicular to the first direction.

In an embodiment, the first light-emitting layer includes a first light-emitting sub-layer, a second light-emitting sub-layer and a third light-emitting sub-layer that are arranged sequentially along the second direction; and where the second light-emitting layer includes a fourth light-emitting sub-layer, a fifth light-emitting sub-layer and a sixth light-emitting sub-layer, where the second direction is perpendicular to the first direction.

The first light-emitting sub-layer and the fourth light-emitting sub-layer emit the light with the same color, and an absolute value of a difference between a wavelength of the light emitted by the first light-emitting sub-layer and a wavelength of the light emitted by the fourth light-emitting sub-layer is less than or equal to 20 nm.

The second light-emitting sub-layer and the fifth light-emitting sub-layer emit the light with the same color, and an absolute value of a difference between a wavelength of the light emitted by the second light-emitting sub-layer and a wavelength of the light emitted by the fifth light-emitting sub-layer is less than or equal to 20 nm.

The third light-emitting sub-layer and the sixth light-emitting sub-layer emit the light with the same color, and an absolute value of a difference between a wavelength of the light emitted by the third light-emitting sub-layer and a wavelength of the light emitted by the sixth light-emitting sub-layer is less than or equal to 20 nm.

In an embodiment, the first light-emitting sub-layer, the second light-emitting sub-layer and the third light-emitting sub-layer independently emit light selected from a group consisting of red light, green light and blue light. The fourth light-emitting sub-layer, the fifth light-emitting sub-layer and the sixth light-emitting sub-layer respectively emit light selected from a group consisting of red light, green light and blue light.

In an embodiment, the first charge generation layer further includes an N-type dopant selected from a group consisting of alkali metals, oxides of alkali metals, alkaline earth metals, oxides of alkaline earth metals, transition metals and oxides of transition metals.

In an embodiment, any one of the first light-emitting sub-layer, the second sub-light emitting layer, the third sub-light emitting layer, the fourth sub-light emitting layer, the fifth sub-light emitting layer and the sixth sub-light emitting layer sub-emitting layers includes: a first host material and a second host material. The first host material and the second host material constitute an exciplex. The difference between a wavelength corresponding to a peak of the emission spectrum of the exciplex and a wavelength corresponding to a peak of the emission spectrum of the first host material is greater than or equal to 20 nm, and the difference between the wavelength corresponding to the peak of the emission spectrum of the exciplex and a wavelength corresponding to a peak of the emission spectrum of the second host material is greater than or equal to 20 nm. The molecular distance between the HOMO unit of the first host material and the LUMO unit of the second host material is greater than or equal to 3.4 Å and less than or equal to 5 Å.

In an embodiment, any one of the first light-emitting sub-layer, the second sub-light emitting layer, the third sub-light emitting layer, the fourth sub-light emitting layer, the fifth sub-light emitting layer and the sixth sub-light emitting layer sub-emitting layers includes: a first host material and a second host material. The first host material and the second host material are isomers or homologues. An absolute value of a difference between the wavelength corresponding to the peak of the emission spectrum of the first host material and the wavelength corresponding to the peak of the emission spectrum of the second host material is less than 10 nm. Both the first host material and the second host material may be derivatives of anthracene.

In an embodiment, the mass ratio between the first host material and the second host material is greater than or equal to 1/99 and less than or equal to 99.

According to the present disclosure, a display panel including the light-emitting device described above is provided.

According to the present disclosure, a display apparatus including the display panel described above is provided.

Additional aspects and advantages of the present disclosure will be set forth in part in the following description, which will become apparent from the following description or be learned by practice of the present disclosure.

### BRIEF DESCRIPTION OF DRAWINGS

Accompanying drawings herein are incorporated into and constitute a part of the specification, illustrate embodiments consistent with the present disclosure, and are combined with the description to explain the principle of the present disclosure.

FIG. 1 is a schematic structure diagram of a light-emitting device according to an embodiment of the present disclosure.

FIG. 2 is a schematic structure diagram of a light-emitting device according to another embodiment of the present disclosure.

FIG. 3 is a schematic structure diagram of a light-emitting device according to another embodiment of the present disclosure.

### IN THE DRAWINGS

1—anode; 2—light-emitting unit; 21—first light-emitting unit; 22—second light-emitting unit;
10a—first light-emitting region of the light-emitting device; 10b—second light-emitting region of the light-emitting device; 10c—third light-emitting region of the light-emitting device;
211—hole injection layer; 212—first hole transport layer; 213—first electron-barrier layer; 214—first light-emitting layer; 215—first hole barrier layer;
213a—first electron barrier sub-layer; 213b—second electron barrier sub-layer; 213c—third electron barrier sub-layer;
214a—first light-emitting sub-layer; 214b—second light-emitting sub-layer; 214c—third light-emitting sub-layer;
221—second hole transport layer; 222—second electron barrier layer; 223—second light-emitting layer; 224—second hole barrier layer; 225—electron transport layer;
222a—fourth electron barrier sub-layer; 222b—fifth electron barrier sub-layer; 222c—sixth electron barrier sub-layer;
223a—fourth light-emitting sub-layer; 223b—fifth light-emitting sub-layer; 223c—sixth light-emitting sub-layer;
3—charge generation layer; 31—first charge generation layer; 32—second charge generation layer; and
4—cathode.

### DETAILED DESCRIPTION

Exemplary embodiments will be described in detail herein, examples of which are illustrated in the accompanying drawings. When the following descriptions involve the drawings, like numerals in different drawings refer to like or similar elements unless otherwise indicated. Embodiments described in the illustrative examples below are not intended to represent all embodiments consistent with the present disclosure. Rather, they are merely embodiments of devices and methods consistent with some aspects of the present disclosure as recited in the appended claims.

Terms used in the present disclosure is only for the purpose of describing particular embodiments and is not intended to limit the present disclosure. As used in the present disclosure and the appended claims, the singular forms “a”, “said” and “the” are intended to include the plural” and “the” are intended to include the plural forms as well, unless the context clearly dictates otherwise. It should also be understood that the term “and/or” as used herein refers to and includes any or all possible combinations of one or more associated listed items.

First, the terms that may be involved in present disclosure are explained.

The charge generation layer (CGL) refers to space thin layers with positive charges or negative charges formed at both sides of a contact surface between a P-type semiconductor and an N-type semiconductor or between a metal and a semiconductor during the process of forming a “junction” after the P-type semiconductor and the N-type semiconductor or the metal and the semiconductor are contacted.

HOMO-LUMO energy levels collectively refer to Frontier Molecular Orbitals. HOMO and LUMO refer to the Highest Occupied Molecular Orbital and the Lowest Unoccupied Molecular Orbital respectively. According to the Frontier Molecular Orbital theory, HOMO and LUMO collectively refer to the Frontier Orbitals, and electrons in the Frontier Molecular Orbital refer to Frontier Orbital electrons. The energy difference between HOMO and LUMO refers to the “energy band gap”. This energy difference refers to the HOMO-LUMO energy level, which can sometimes be used to measure whether a molecule is easy to be excited, and the smaller the band gap, the easier the molecule is excited.

The inventive ideas for the present disclosure include follows.

In the field of organic semiconductor technology applications, OLED, as a new type of flat panel display, has gradually received more attention. OLED is an active light-emitting device with the advantages of high brightness and color saturation, ultra-thinness, wide viewing angle, low power consumption, extremely high response speed and flexibility. OLED includes an anode, a cathode, and a light-emitting layer between the anode and the cathode. The light-emitting principle of the OLED is after injecting the holes and the electrons from the anode and the cathode into the light-emitting layer respectively, when the electrons and the holes meet in the light-emitting layer, the electrons and the holes recombine to generate excitons, which emit light while transitioning from the excited state to the ground state. In order to obtain high current efficiency, people have designed a way of stacking two or more light-emitting units, which is called stacked OLEDs. The stacked OLEDs have broad application space due to their higher efficiency and longer life service than that of traditional OLEDs. In the stacked OLEDs, two or more light-emitting units are mainly connected together through connecting layers. Compared with the traditional OLED, the stacked OLED has higher luminous efficiency, and its luminous efficiency can be multiplied with the increase of the number of the light-emitting units. Moreover, when tested at the same current density, the degradation characteristics of the stacked OLEDs and the traditional OLEDs are the same. However, because initial brightness of the stacked OLED is larger, when the initial brightness of the stacked OLED is converted to the initial brightness which is same as the initial brightness of the traditional OLED, the service life of the stacked OLED will be longer than the service life of the traditional OLED. The connecting layer between two stacked light-emitting units is called a charge generation layer.

An electron injection layer EIL, an electron transport layer ETL, a hole injection layer HIL, a hole transport layer HTL, and a charge generation layer CGL are usually required between two light-emitting layers, so that the electrons and the holes can be well generated and transported between the two light-emitting layers, thereby achieving full recombination of the electrons and the holes in the light-emitting layers. When there are many light-emitting units in a stacked OLED, the three processes of charge generation, transport and injection all have significant impacts on the performance of the device. With the development of organic light-emitting devices, the composition of each compound applied to each organic material layer is different, which may result a big difference in the overall performance of the device. Therefore, a good match between materials of different functional layers is required to ensure that the charges can be efficiently generated, injected, transported, recombined, and luminescence. Under the condition of an external positive electric field, the charge generation layer can generate the holes and the electrons, and the generated holes and electrons are then separated. The holes are transported to the light-emitting layer close to the P-type CGL through the hole transport layer, and the electrons are transported to the light-emitting layer close to the N-type CGL through the electron transport layer. It can be seen that the efficient charge generation, the fast charge transfer, and the effective injection are the keys to achieving the high efficiency and the long service life of the stacked OLEDs.

The charge generation layer structure in the stacked OLEDs not only plays a role in connecting the individual OLED units, but more importantly, the charge generation layer generates the charges and can quickly transport and inject the generated charges into the light-emitting unit. In addition, the charge generation layer also needs to have high light transmissibility in the visible light range and an appropriate thickness that matches the entire device, so that the light is emitted at a point where the interference is enhanced. Therefore, optimizing the material composition of the charge generation layer and optimizing the matching between the charge generation layer and the film layers of the adjacent light-emitting units are the keys to obtaining the stacked OLEDs with high performance.

According to the present discourse, a light-emitting device, a display panel and a display apparatus are provided, which are intended to solve the above technical problems of the prior art.

The light-emitting device, the display panel and the display apparatus in the embodiments of the present disclosure will be described in detail below with reference to the accompanying drawings. Features in the embodiments described below may complement each other or be combined with each other without conflicts.

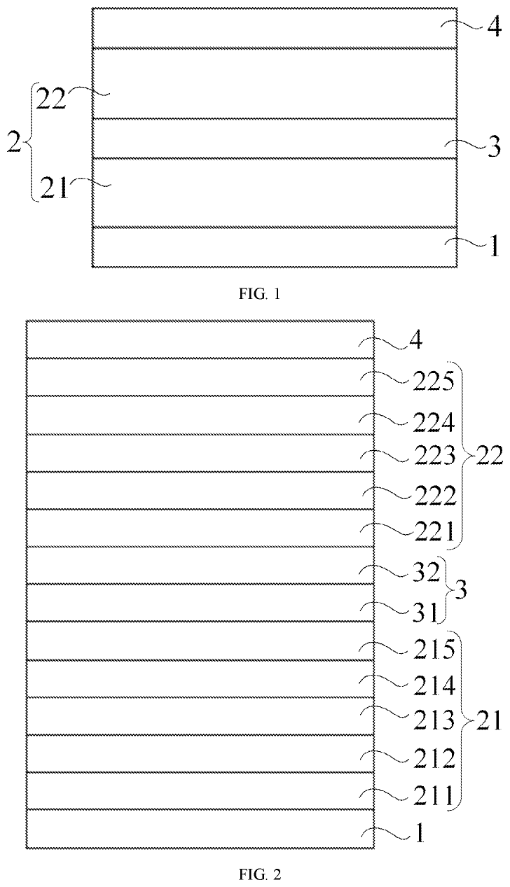

Referring to FIGS. 1 and 2, the embodiments of the present disclosure provide a light-emitting device, including: an anode 1 and a cathode 4 which are disposed oppositely, a light-emitting unit 2 and a charge generation layer 3. The light-emitting unit 2 is between the anode 1 and the cathode 4, where the light-emitting unit 2 includes a first light-emitting unit 21 and a second light-emitting unit 22 which are stacked sequentially along a first direction. The charge generation layer 3 is between the first light-emitting unit 21 and the second light-emitting unit 22. The charge generation layer 3 includes: a first charge generation layer 31 and a second charge generation layer 32 which are stacked sequentially along the first direction. The first charge generation layer 31 includes a first type compound. The second charge generation layer 32 includes a second type compound and a third type compound. The first direction is a direction from the anode 1 to the cathode 4.

The first type compound has a structure shown in formula (I):

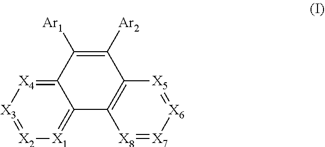

In the formula (I), X₁ to X₈ are the same or different, each of X₁ to X₈ is independently selected from nitrogen or R₁, and the X₁ to X₈ include at least two nitrogen atoms. R₁ is independently selected from hydrogen, deuterium, substituted or unsubstituted C₁ to C₆₀ alkyl group, substituted or unsubstituted C₂ to C₆₀ alkenyl group, substituted or unsubstituted C₂ to C₆₀ alkynyl group, substituted or unsubstituted C₁ to C₆₀ alkoxy group, substituted or unsubstituted C₃ to C₁₀ ring alkyl, substituted or unsubstituted C₁ to C₁₀ heterocycloalkyl, substituted or unsubstituted C₃ to C₁₀ cycloalkenyl, substituted or unsubstituted C₁ to C₁₀ heterocycloalkenyl, substituted or unsubstituted C₆ to C₆₀ aryl group, substituted or unsubstituted C₆ to C₆₀ aryloxy group, substituted or unsubstituted C₆ to C₆₀ arylthio group, substituted or unsubstituted C₁ to C₆₀ heteroaryl group, substituted or unsubstituted monovalent non-aromatic condensed polycyclic group, or substituted or unsubstituted monovalent non-aromatic condensed heteropolycyclic group. Ar₁ and Ar₂ are the same or different, each of the Ar₁ and Ar₂ is independently selected from: hydrogen, deuterium, tritium, halogen, cyano, nitro, C₆ to C₆₀ aryl, C₂ to C₆₀ heterocyclic group containing at least one heteroatom from O, N, S, Si and P, C₃ to C₆₀ aliphatic ring and C₆ to C₆₀ aromatic ring fused ring group, C₁ to C₅₀ alkyl group, C₂ to C₂₀ alkenyl group, C₂ to C₂₀ alkynyl group, C₁ to C₃₀ alkoxy group, C₆ to C₃₀ aryloxy group, C₃ to C₆₀ alkylsilyl group, C₈ to C₆₀ arylsilyl group or C₈ to C₆₀ alkylarylsilyl group.

The second type compound has a structure shown shown in formula (II):

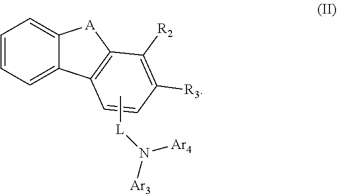

In the formula (II), A may be O, S, C, N, or Si. L indicates a direct bond, independently selected from: substituted or unsubstituted phenyl group, substituted or unsubstituted biphenyl group, substituted or unsubstituted terphenyl group, substituted or unsubstituted fluorenyl group, substituted or unsubstituted adamantane group, substituted or unsubstituted heteroaryl group. The substitution conditions of R₂ and R₃ are the same as the substitution condition of R₁. Ar₃ and Ar₄ are the same or different, each of the Ar₃ and Ar₄ is independently selected from: substituted or unsubstituted phenyl group, substituted or unsubstituted biphenyl group, substituted or unsubstituted naphthalene group, substituted or unsubstituted dibenzofuran group, substituted or unsubstituted carbazole group, and substituted or unsubstituted fluorenyl group.

The third type compound has a structure shown in formula (III):

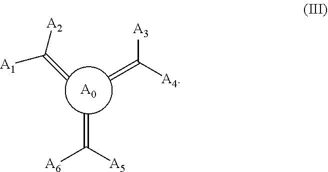

In the formula (III), each of the A₁ to A₆ is independently selected from: substituted or unsubstituted halogen, substituted or unsubstituted cyano, substituted or unsubstituted aldehyde group, substituted or unsubstituted carbonyl group, substituted or unsubstituted carboxyl group, substituted or unsubstituted sulfonic acid group, substituted or unsubstituted nitro group, aryl group substituted by an electron-withdrawing group, heteroaryl substituted by an electron-withdrawing group. A₀ may be a three-membered ring, a four-membered ring, a five-membered ring, or a six-membered ring.

According to the above embodiments, it can be seen that the charge generation layer 3 in the light-emitting device provided by the present disclosure is composed of a second charge generation layer 32 and a first charge generation layer 31 which are stacked. By optimizing the material type of the second charge generation layer 32 or the first charge generation layer 31, the process of generation, transport and injection of holes and electrons can be optimized to ensure the effective injection and transport of the charges into the first light-emitting unit 21 and the second light-emitting unit 22, thereby improving the luminous efficiency and the service life of the stacked OLED light-emitting device.

Specifically, when the heterocyclic compound represented by the formula (I) provided in this embodiment is used as a material of the first charge generation layer 31, the first charge generation layer 31 has a lower LUMO energy level, which reduces the energy barrier at the interface between the first charge generation layer 31 and the second charge generation layer 32, thereby inhibiting the degradation at the interface. In addition, the heterocyclic compound represented by the formula (I) has excellent electron transport ability, and based on the above structure, the heterocyclic compound can increase the electron mobility in the organic light-emitting device and prevent the reduction of the luminous efficiency of the light-emitting device under low current conditions. In addition, the heterocyclic compound represented by the formula (I) contains a large conjugate plane, when the heterocyclic compound is applied to the charge generation layer 3, the electron transmission characteristic can be effectively improved.

Meanwhile, the compound represented by the formula (II) contains electron-rich arylamine and electron-rich dibenzo groups, and can form conjugate π bond with the adjacent group, so that the electrons in the molecule have high delocalization, thereby resulting in a higher mobility of this type of material to ensure the rapid transport of the carriers. Therefore, when the compound represented by the formula (II) is applied to the material of the second charge generation layer 32, the charge transfer efficiency of the charge generation layer 32 can be improved.

In addition, the third type compound represented by the formula (III) contains a large number of electron-withdrawing groups, and the third type compound represented by the formula (III) has a lower LUMO energy level. After the second type compound represented by the formula (II) is mixed with the third type compound represented by the formula (III), the second type compound generates holes, and the electron-withdrawing group in the third type compound absorbs the HOMO unit in the second type compound, so that the mixture of the second type compound and the third type compound has a lower LUMO energy level, which contributes to generate the charges.

It should be noted that in the formula (II), A indicates any one of O, S, C, N, or Si. When A indicates O or S, there are two chemical bonds around the O atom or the S atom, which can be directly connected with two phenyl groups at both sides of A, without additionally connecting other functional groups. When A is N, since the N atom forms three chemical bonds in the organic compound, in addition to connecting the phenyl groups at both sides, another bond is connected to a common functional group. When A is C or Si, four chemical bonds are formed, and in addition to connecting the phenyl groups at both sides, the other two bonds are connected to the common functional groups.

In some embodiments, the doping ratio of the third type compound represented by theformula (III) in the second charge generation layer 32 ranges from 2% to 5%. Specifically, if the third type compound is doped too much, as the third type compound contains electron-withdrawing groups, the risk of crosstalk in the circuit of the light-emitting unit 2 may be caused. Meanwhile, because the turn-on voltage of the red sub-pixel is low, it is very likely to cause that the red sub-pixel to be mistakenly lit, reduce the sensitivity of the driving circuit in the light-emitting unit 2, and affect the light-emitting effect.

In an embodiment, the doping ratio of the third type compound in the second charge generation layer 32 is 5%.

In some embodiments, the anode 1 may be made of a high work function electrode material, such as transparent conductive oxide materials (such as ITO (Indium Tin Oxide), IZO (Indium Zinc Oxide) or IGZO (Indium Gallium Zinc Oxide), etc.), or the anode 1 may be a composite electrode formed by ITO/Ag/ITO, Ag/IZO, CNT/ITO (CNT refers to Carbon nano-metre tube, the same below), CNT/IZO, GO/ITO (GO refers grapheneoxide, the same below), GO/IZO, etc.

In some embodiments, the cathode 4 may be made of the metal material such as Mg (magnesium), Ag (silver) or Al (aluminum), or may be made of the alloy material such as Mg:Ag alloys, where the ratio of Mg element and Ag element may range from (3:7) to (1:9).

In an embodiment, the first type compound has a structure shown in any one of following formulas:

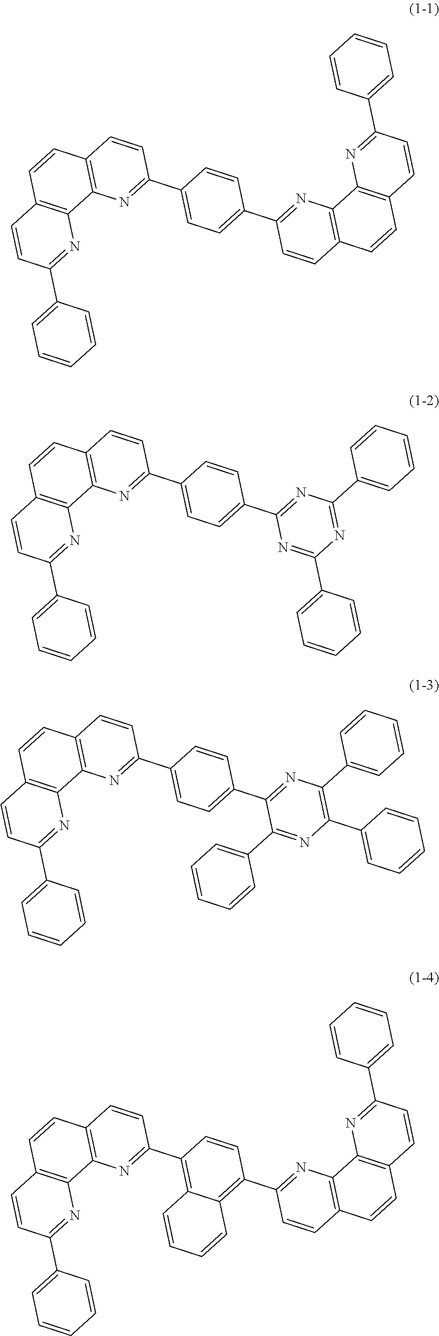 [SMILES: c1ccc(-c2ccc3ccc4ccc(-c5ccc(-c6ccc7ccc8ccc(-c9ccccc9)nc8c7n6)cc5)nc4c3n2)cc1 ; c1ccc(-c2ccc3ccc4ccc(-c5ccc(-c6nc(-c7ccccc7)nc(-c7ccccc7)n6)cc5)nc4c3n2)cc1 ; c1ccc(-c2ccc3ccc4ccc(-c5ccc(-c6nc(-c7ccccc7)c(-c7ccccc7)nc6-c6ccccc6)cc5)nc4c3n2)cc1 ; c1ccc(-c2ccc3ccc4ccc(-c5ccc(-c6ccc7ccc8ccc(-c9ccccc9)nc8c7n6)c6ccccc56)nc4c3n2)cc1]

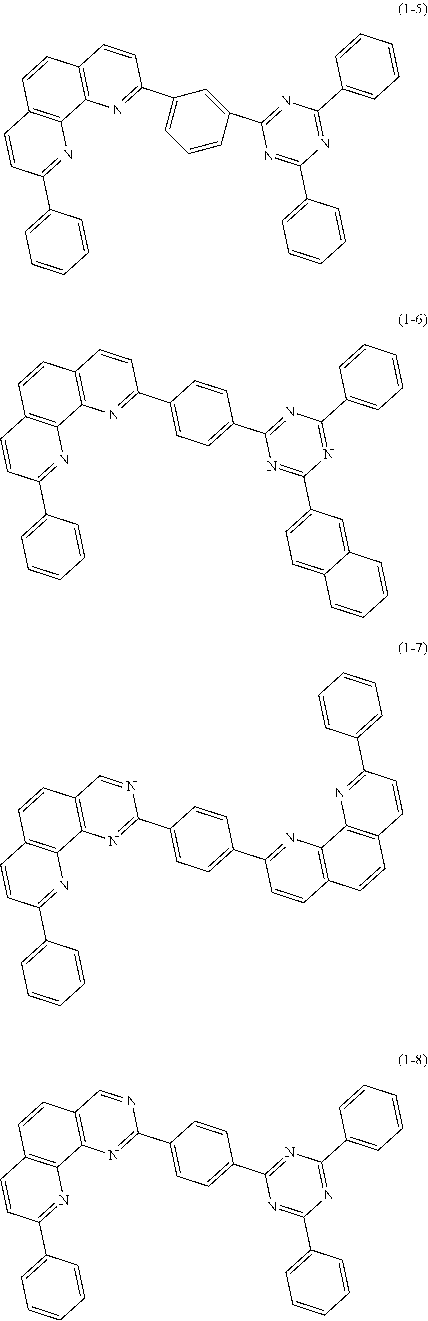 [SMILES: c1ccc(-c2ccc3ccc4ccc(-c5cccc(-c6nc(-c7ccccc7)nc(-c7ccccc7)n6)c5)nc4c3n2)cc1 ; c1ccc(-c2ccc3ccc4ccc(-c5ccc(-c6nc(-c7ccccc7)nc(-c7ccc8ccccc8c7)n6)cc5)nc4c3n2)cc1 ; c1ccc(-c2ccc3ccc4ccc(-c5ccc(-c6ncc7ccc8ccc(-c9ccccc9)nc8c7n6)cc5)nc4c3n2)cc1 ; c1ccc(-c2ccc3ccc4cnc(-c5ccc(-c6nc(-c7ccccc7)nc(-c7ccccc7)n6)cc5)nc4c3n2)cc1]

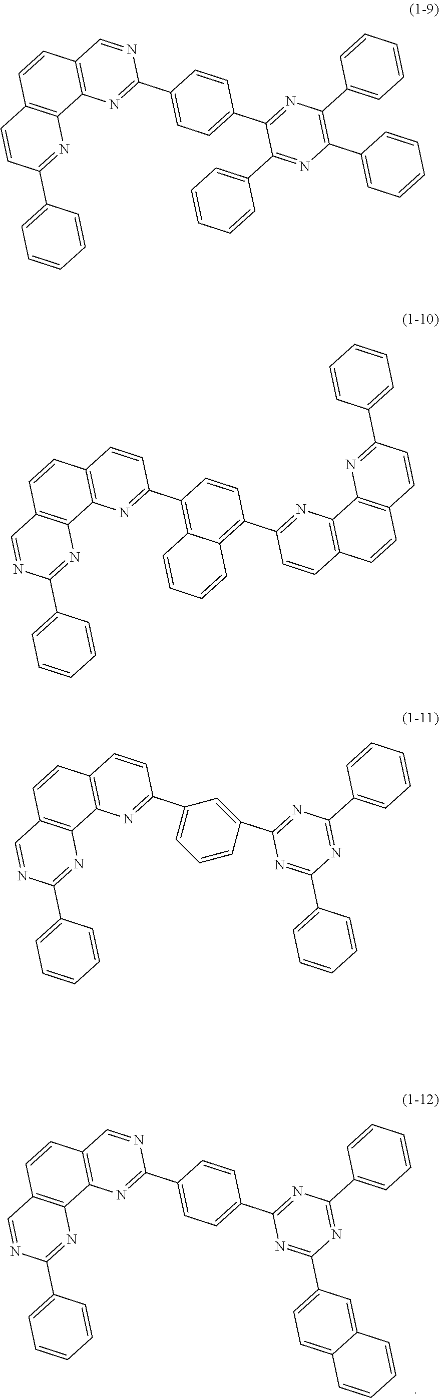 [SMILES: c1ccc(-c2ccc3ccc4cnc(-c5ccc(-c6nc(-c7ccccc7)c(-c7ccccc7)nc6-c6ccccc6)cc5)nc4c3n2)cc1 ; c1ccc(-c2ccc3ccc4ccc(-c5ccc(-c6ccc7ccc8cnc(-c9ccccc9)nc8c7n6)c6ccccc56)nc4c3n2)cc1 ; c1ccc(-c2nc(-c3ccccc3)nc(-c3cccc(-c4ccc5ccc6cnc(-c7ccccc7)nc6c5n4)c3)n2)cc1 ; c1ccc(-c2nc(-c3ccc(-c4ncc5ccc6cnc(-c7ccccc7)nc6c5n4)cc3)nc(-c3ccc4ccccc4c3)n2)cc1]

Specifically, in the first type compound listed above, when the nitrogen substitution positions are symmetrical X₁ and X₈, the structural stability of the first type compound represented by the formula (I) is relatively high. At this time, the 2nd and 9th positions of the heterocyclic compound are prone to degradation which is caused by the negative polaron, so that these two positions are easily substituted by other substituent groups. Specifically refer to the following heterocyclic structure:

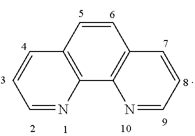 [SMILES: c1cnc2c(c1)ccc1cccnc12]

It should be noted that, in addition to the above-mentioned substitution positions of X₁ and X₈, other substitution positions of the first type compound in the present disclosure may be substituted by nitrogen or R₁, and the formed compound may also be the first type compound in the present disclosure, which is not specifically limited herein.

In an embodiment, the second type compound has a structure shown in any one of following formulas:

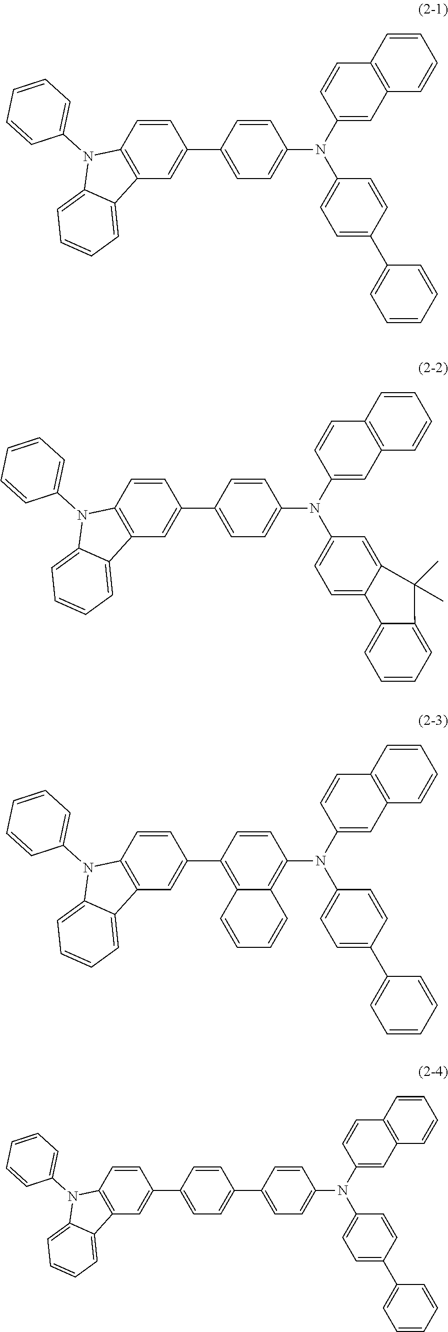 [SMILES: c1ccc(-c2ccc(N(c3ccc(-c4ccc5c(c4)c4ccccc4n5-c4ccccc4)cc3)c3ccc4ccccc4c3)cc2)cc1 ; CC1(C)c2ccccc2-c2ccc(N(c3ccc(-c4ccc5c(c4)c4ccccc4n5-c4ccccc4)cc3)c3ccc4ccccc4c3)cc21 ; c1ccc(-c2ccc(N(c3ccc4ccccc4c3)c3ccc(-c4ccc5c(c4)c4ccccc4n5-c4ccccc4)c4ccccc34)cc2)cc1 ; c1ccc(-c2ccc(N(c3ccc(-c4ccc(-c5ccc6c(c5)c5ccccc5n6-c5ccccc5)cc4)cc3)c3ccc4ccccc4c3)cc2)cc1]

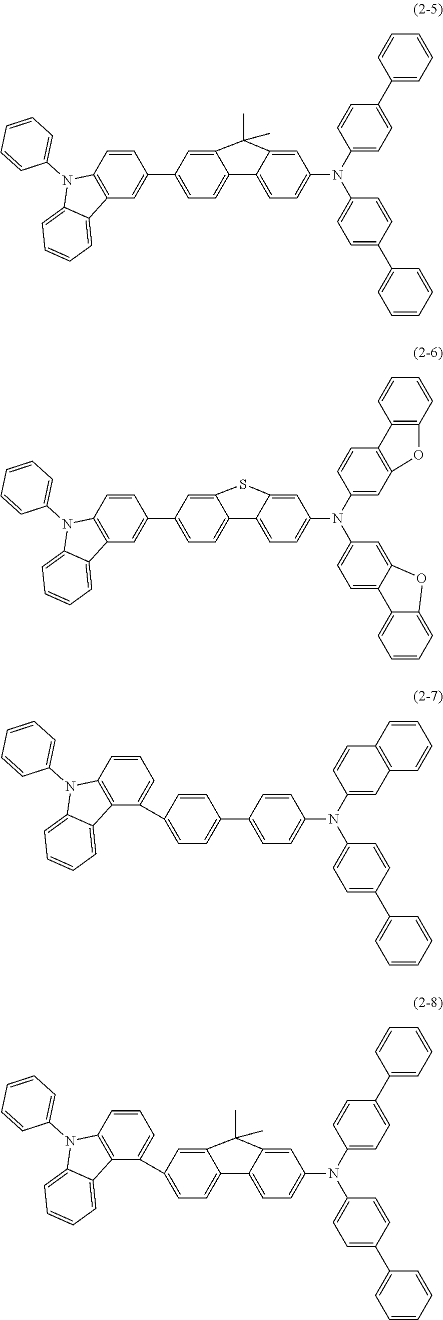 [SMILES: CC1(C)c2cc(-c3ccc4c(c3)c3ccccc3n4-c3ccccc3)ccc2-c2ccc(N(c3ccc(-c4ccccc4)cc3)c3ccc(-c4ccccc4)cc3)cc21 ; c1ccc(-n2c3ccccc3c3cc(-c4ccc5c(c4)sc4cc(N(c6ccc7c(c6)oc6ccccc67)c6ccc7c(c6)oc6ccccc67)ccc45)ccc32)cc1 ; c1ccc(-c2ccc(N(c3ccc(-c4ccc(-c5cccc6c5c5ccccc5n6-c5ccccc5)cc4)cc3)c3ccc4ccccc4c3)cc2)cc1 ; CC1(C)c2cc(-c3cccc4c3c3ccccc3n4-c3ccccc3)ccc2-c2ccc(N(c3ccc(-c4ccccc4)cc3)c3ccc(-c4ccccc4)cc3)cc21]

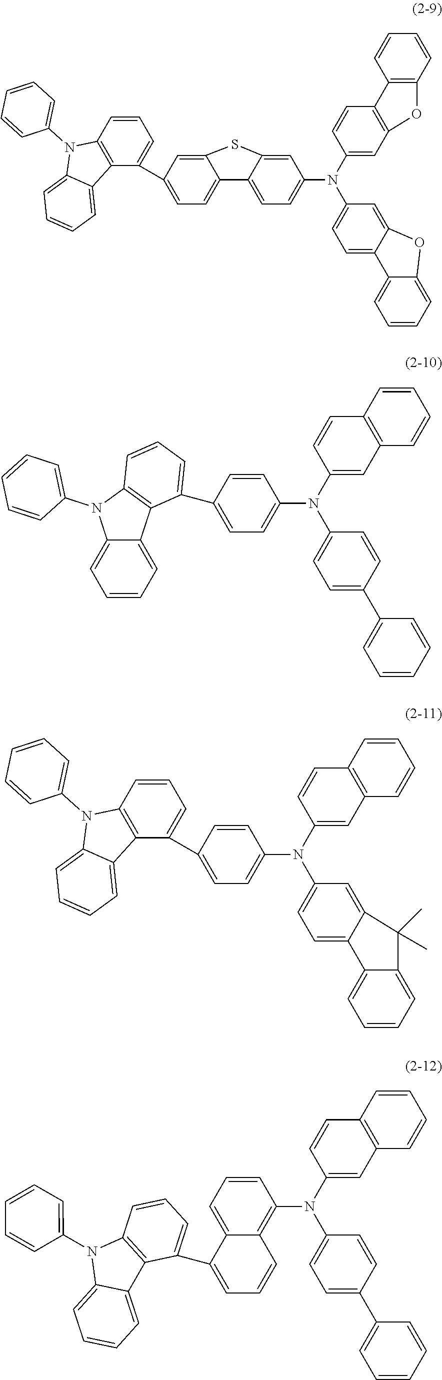 [SMILES: c1ccc(-n2c3ccccc3c3c(-c4ccc5c(c4)sc4cc(N(c6ccc7c(c6)oc6ccccc67)c6ccc7c(c6)oc6ccccc67)ccc45)cccc32)cc1 ; c1ccc(-c2ccc(N(c3ccc(-c4cccc5c4c4ccccc4n5-c4ccccc4)cc3)c3ccc4ccccc4c3)cc2)cc1 ; CC1(C)c2ccccc2-c2ccc(N(c3ccc(-c4cccc5c4c4ccccc4n5-c4ccccc4)cc3)c3ccc4ccccc4c3)cc21 ; c1ccc(-c2ccc(N(c3ccc4ccccc4c3)c3cccc4c(-c5cccc6c5c5ccccc5n6-c5ccccc5)cccc34)cc2)cc1]

In an embodiment, the third type compound has a structure shown in any one of following formulas:

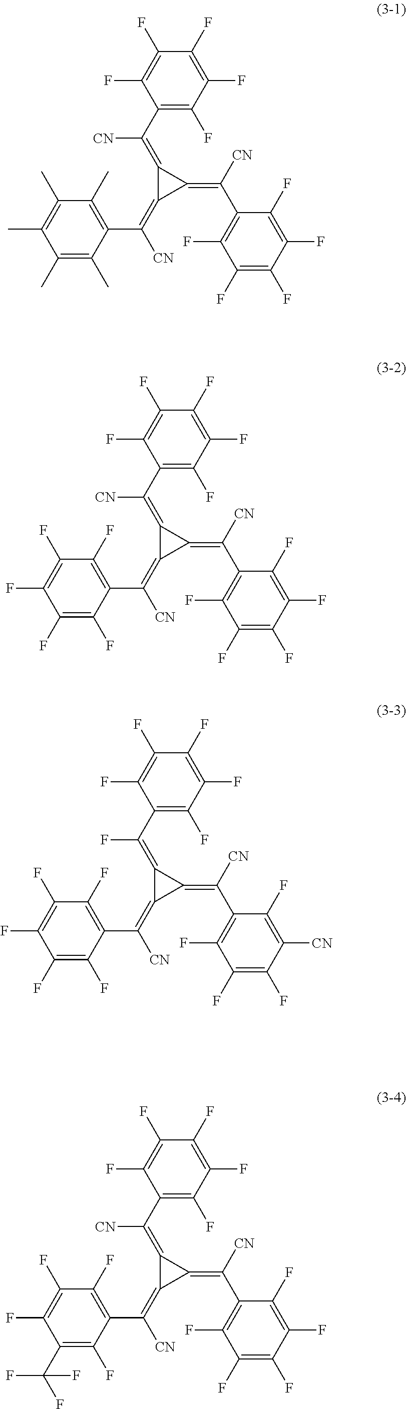

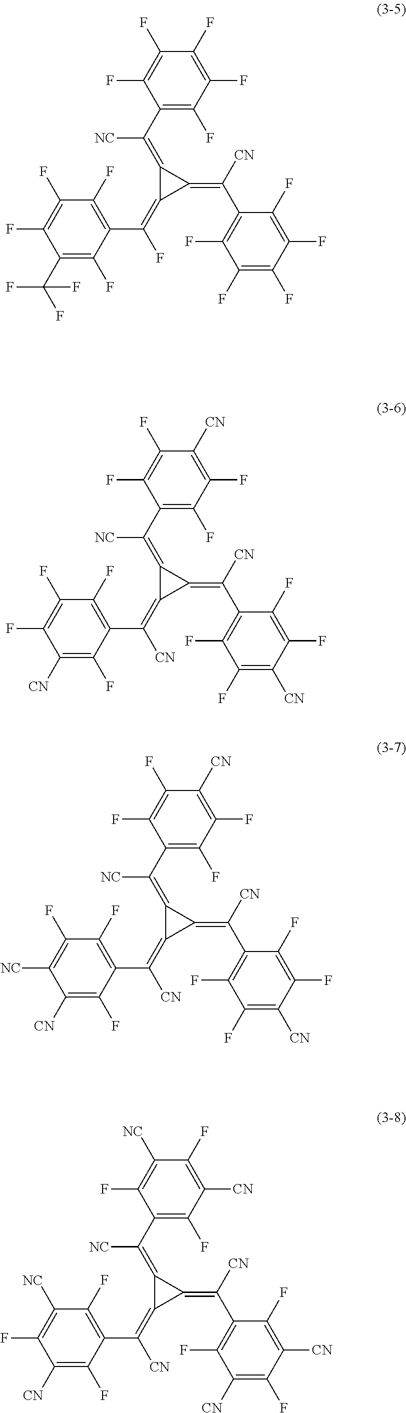

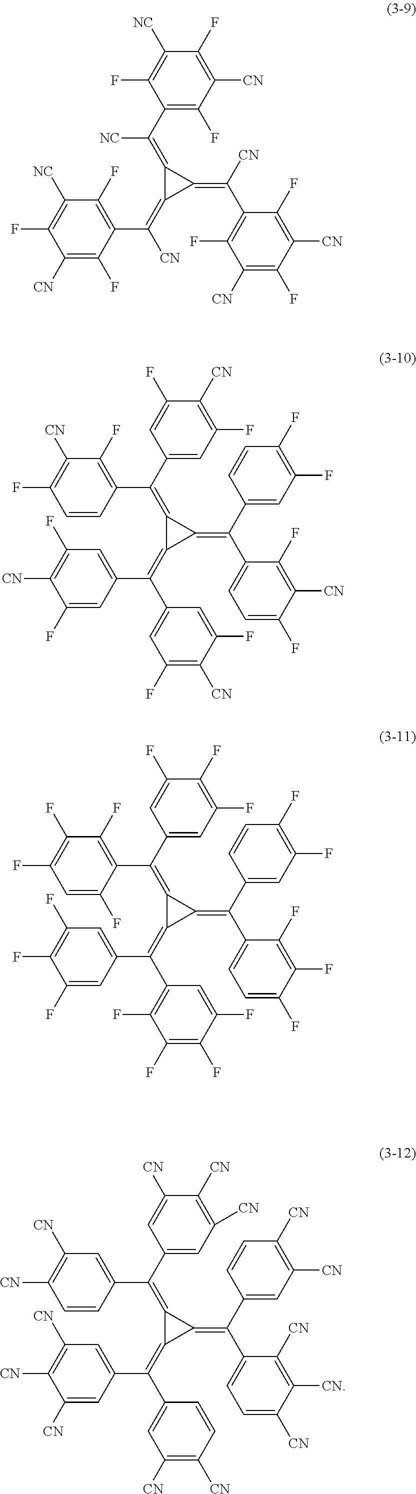

It should be noted that the electron-withdrawing groups are groups with positive charges, including but not limited to aldehyde group, carbonyl group, carboxyl group, halogen atom, sulfonyl group, haloalkyl group, cyanide group and nitro group. The electron-donating groups are groups with negative charges, including but not limited to: alkyl group, aryl group, hydroxyl group, alkoxy group, amino group, substituted amino group, ester and amide groups. Therefore, when a part of the substituted groups of A₁ to A₆ in the compounds listed above are aryl groups, the aryl group is required to be further substituted by an electron-withdrawing group to improve the electron-withdrawing properties of the material.

In some embodiments, the second charge generation layer 32 is formed by the third type compound and the second type compound through the way of co-evaporation, which can enhance the conductivity, to ensure that the combination of charges is formed effectively and the charges are transported effectively.

In some embodiments, the first charge generation layer is an N-type charge generation layer, and the second charge generation layer is a P-type charge generation layer.

In some embodiments, the first light-emitting unit 21 includes: a hole injection layer 211, a first hole transport layer 212, a first electron barrier layer 213, a first light-emitting layer 214 and a first hole barrier layer 215 which are stacked sequentially along the first direction. The absolute value of the difference between the LUMO energy level of the first charge generation layer 31 and the LUMO energy level of the first hole barrier layer 215 is less than or equal to 0.5 eV.

In some embodiments, the hole injection layer 211 may be an inorganic oxide, specifically, it may be molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, etc., or the hole injection layer 211 may be dopants of strong electron-withdrawing systems, such as F4TCNQ, HATCN, PPDN, etc. In addition, P-type doping may be performed in the hole transport material, with a doping thickness of 5 nm to 20 nm, and the hole injection layer 211 is formed by co-evaporation. The formulas of F4TCNQ, HATCN and PPDN are as follows.

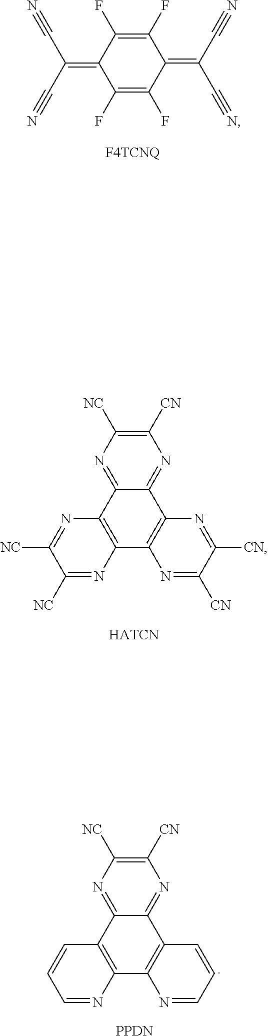

In some embodiments, the first light-emitting unit 21 further includes a first electron transport layer, and the first electron transport layer is disposed at a side of the first hole barrier layer 215 away from the anode 1. In addition, the second light-emitting unit 22 further includes an electron injection layer. The material of the electron injection layer may be the alkali metal or the metal, such as LiF, Yb, Mg, Ca or compounds thereof.

In some embodiments, the second light-emitting unit 22 includes: a second hole transport layer 221, a second electron barrier layer 222, a second light-emitting layer 223, a second hole barrier layer 224 and an electron transport layer 225 which are sequentially stacked along the first direction. The absolute value of the difference between the HOMO energy level of the second charge generation layer 32 and the HOMO energy level of the second hole transport layer 221 is less than or equal to 0.3 eV.

In some embodiments, both the first hole transport layer 212 and the second hole transport layer 221 may be made of aromatic amines or carbazoles materials, such as NPB, TPD, BAFLP, DFLDPBi, TCTA, TAPC, etc. The formulas of NPB, TCTA and TAPC are as follows.

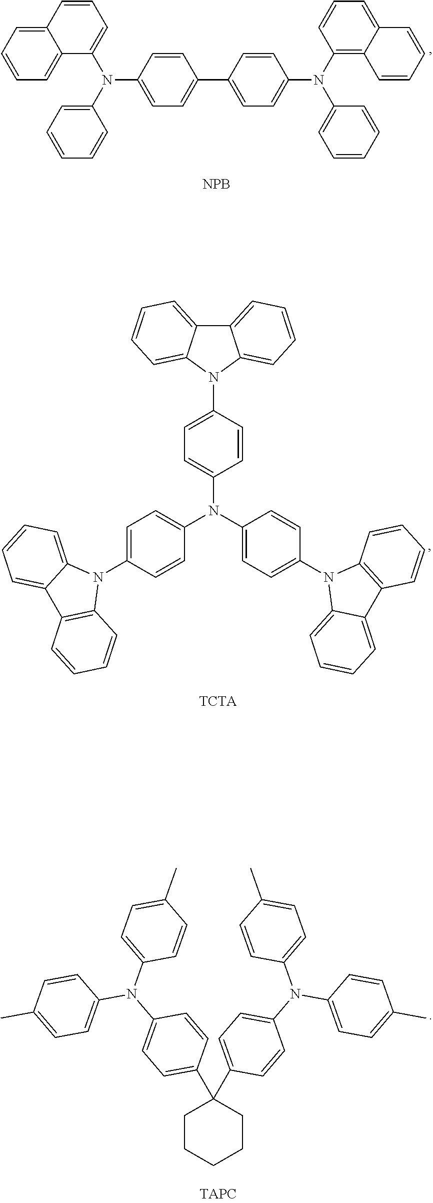

In some embodiments, both the first electron barrier layer 213 and the second electron barrier layer 222 have good hole transport properties and may be DBTA, PAPB, etc. The formulas of DBTA and PAPB are as follows.

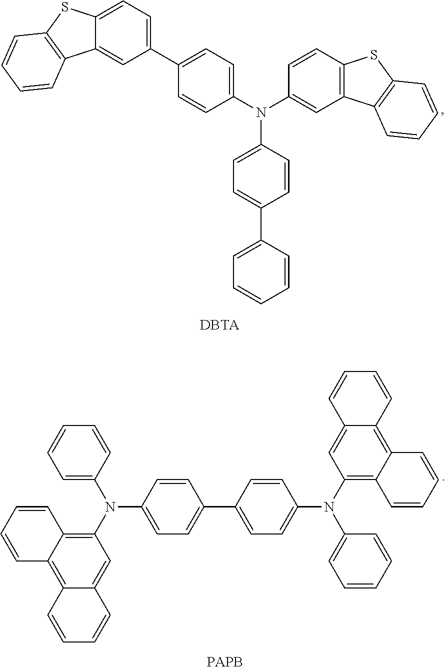 [SMILES: c1ccc(-c2ccc(N(c3ccc(-c4ccc5sc6ccccc6c5c4)cc3)c3ccc4sc5ccccc5c4c3)cc2)cc1 ; "DBTA" ; c1ccc(N(c2ccc(-c3ccc(N(c4ccccc4)c4cc5ccccc5c5ccccc45)cc3)cc2)c2cc3ccccc3c3ccccc23)cc1]

In some embodiments, the side of the light-emitting layer away from the anode 1 is also provided with a light-emitting auxiliary layer, which may be the aromatic amine or carbazole material, such as CBP, PCzPA, etc. The formula of CBP is as follows.

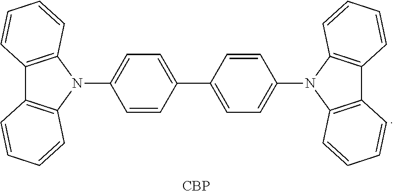 [SMILES: c1ccc2c(c1)c1ccccc1n2-c1ccc(-c2ccc(-n3c4ccccc4c4ccccc43)cc2)cc1 ; "CBP"]

In some embodiments, the materials of the first hole barrier layer 215, the second hole barrier layer 224 and the electron transport layer 225 in the present disclosure may be the aromatic heterocyclic compounds, such as benzimidazole derivatives, imidazolopyridine derivatives, imidazole derivatives (e.g., benzimidazolophenanthridine derivatives, etc.), yrimidine derivatives, triazine derivatives and other zine derivatives, quinoline derivatives, isoquinoline derivatives, the nitrogen-containing compounds with a six-membered ring structure (e.g., phenanthroline derivatives, etc.) and further include the compound having the substituent group of the phosphine oxide on the heterocyclic ring (e.g., OXD-7, TAZ, p-EtTAZ, BPhen, BCP, TPBi, etc.), where the formulas of BPhen and TPBi are as follows.

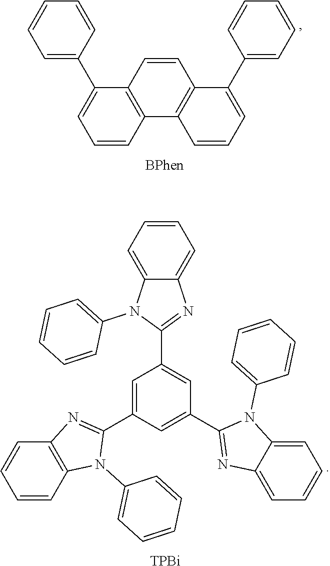

According to the above embodiments, it can be seen that the absolute value of the difference between the HOMO energy levels of the charge generation layer 3 and its adjacent film layer or the LUMO energy levels between the charge generation layer 3 and its adjacent film layer in the present disclosure is within a range of values, which can reduce the energy level transmission barrier between the charge generation layer 3 and its adjacent film layer, is conducive to the generation of the charges, can accelerate the electron transmission efficiency and is more conducive to the regulation of the balance for the charge transport.

In an example, the absolute value of the difference between the LUMO energy level of the first charge generation layer 31 and the LUMO energy level of the first hole barrier layer 215 is 0.1 eV, 0.2 eV, 0.3 eV, 0.4 eV, or 0.5 eV.

In an example, the absolute value of the difference between the HOMO energy level of the second charge generation layer 32 and the HOMO energy level of the second hole transport layer 221 is 0.1 eV, 0.2 eV, or 0.3 eV.

By testing the dipole moment and the glass transition temperature (Tg) of (1-1), (1-2), (1-3) in the first type compound represented by the formula (I) in the present disclosure and the comparative N-CGL material, the relative properties of the two types of materials may be compared. The formula of the comparative N-CGL is shown in the following formula.

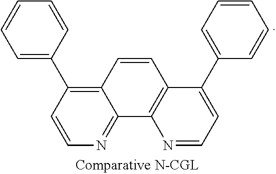 [SMILES: c1ccc(-c2ccnc3c2ccc2c(-c4ccccc4)ccnc23)cc1]

For example, the dipole moment and the glass transition temperature (Tg) of the above formula (1-1), (1-2), (1-3) and the comparative N-CGL are shown in Table 1 below.

TABLE 1
Physical properties of N-CGL of the present
disclosure and the comparative N-CGL

| Material | Dipole moment (D) | Tg (° C.) |
|---|---|---|
| (1-1) | 6.2 | 142 |
| (1-2) | 5.54 | 152 |
| (1-3) | 5.75 | 149 |
| Comparative N-CGL | 3.86 | <120 |

It should be noted that, the product of the distance between the positive charge center and the negative charge center and the amount of charge of the charge center refers to the dipole moment. The larger the dipole moment is, the better the electron injection function of the material is.

The glass transition temperature Tg determines the thermal stability of the material during the evaporation process. The higher the Tg is, the better the thermal stability of the material is. For example, the glass transition temperature is detected by a differential scanning calorimeter (DSC) in a test environment where the test atmosphere is nitrogen, the heating rate is 10° C./min, and the temperature range is from 50° C. to 300° C.

Therefore, it can be seen from Table 1 that the dipole moment of the first type compound material shown in the above formulas (1-1), (1-2), and (1-3) is larger than the dipole moment of the comparative N-CGL, and the glass transition temperature of the first type compound material shown in the above formula (1-1), (1-2), and (1-3) is greater than the glass transition temperature of the comparative N-CGL, which indicates that electron injection function and better thermal stability of the N-CGL formed by the first type compound material provided by the present disclosure is better than those of the comparative N-CGL.

In some embodiment, a dipole moment of the charge generation layer 3 is greater than 4 D (Debye), which can ensure that the charge generation layer 3 has better electron injection characteristics.

In some embodiments, the electron mobility of the first charge generation layer 31 is greater than the electron mobility of the first hole barrier layer 215. The electron transfer efficiency of the electrons transferred from the first charge generation layer 31 to the first light-emitting unit 21 can be enhanced, so that the electrons and the electrons holes generated by the anode 1 adjacent to the first light-emitting unit 21 may meet in the first light-emitting layer 214, and the electrons and the holes recombine to generate the excitons which emit light while the state of the excitons is changed from the excited state to the ground state.

In some embodiments, the hole mobility of the second charge generation layer 32 is greater than the hole mobility of the second hole transport layer 221. The electron transfer efficiency of the electrons transferred from the second charge generation layer 32 to the second light-emitting unit 22 can be enhanced, so that the holes and the electrons generated by the cathode 4 adjacent to the second light-emitting unit 22 may meet in the second light-emitting layer 223, and the electrons and the holes recombine to generate the excitons which emit light while the state of the excitons is changed from the excited state to the ground state.

In some embodiments, the ratio between the electron mobility of the first hole barrier layer 215 and the electron mobility of the second hole barrier layer 224 is greater than or equal to 0.1 and less than or equal to 10.

In an example, the ratio between the electron mobility of the first hole barrier layer 215 and the electron mobility of the second hole barrier layer 224 is 0.1, 1, 3, 5, 7, 10, which is not limited herein.

In some embodiments, the ratio between the hole mobility of the first hole transport layer 212 and the hole mobility of the second hole transport layer 221 is greater than or equal to 0.1 and less than or equal to 10.

In an example, the ratio between the hole mobility of the first hole transport layer 212 and the hole mobility of the second hole transport layer 221 is 0.1, 1, 3, 5, 7, 10, which is not limited herein.

According to the above embodiments, it can be known that by setting the ratio between the electron mobility of the first hole barrier layer 215 and the electron mobility of the second hole barrier layer 224 to be greater than or equal to 0.1 and less than or equal to 10, or the ratio of the hole mobility of the first hole transport layer 212 and the hole mobility of the second electron transport layer 221 is greater than or equal to 0.1 and less than or equal to 10, it can be achieved that the orthographic projections of the recombination region of the first light-emitting unit 21 and the recombination region of the second light-emitting unit 22 in the first direction are basically overlapped, thereby ensuring that the light emitted by the light-emitting device has no obvious color separation and ultimately presents better lighting effect. The first direction is a direction from the anode 1 to the cathode 4.

In some embodiment, the first light-emitting layer includes a first light-emitting sub-layer 214a, a second light-emitting sub-layer 214b and a third light-emitting sub-layer 214c which are arranged sequentially along the second direction; the second light-emitting layer includes a fourth light-emitting sub-layer 223a, a fifth light-emitting sub-layer 223b and a sixth light-emitting sub-layer 223c which are arranged sequentially along the second direction, where the second direction is perpendicular to the first direction;

The first light-emitting sub-layer 214a and the fourth light-emitting sub-layer 223a emit light with the same color, and an absolute value of a difference between a wavelength of the light emitted by the first light-emitting sub-layer 214a and a wavelength of the light emitted by the fourth light-emitting sub-layer 223a is less than or equal to 20 nm.

In some embodiment, the second light-emitting sub-layer 214b and the fifth light-emitting sub-layer 223b emit light with the same color, and an absolute value of a difference between a wavelength of the light emitted by the second light-emitting sub-layer 214b and a wavelength of the light emitted by the fifth light-emitting sub-layer 223b is less than or equal to 20 nm.

In some embodiment, the third light-emitting sub-layer 214c and the sixth light-emitting sub-layer 223c emit light with the same color, and an absolute value of a difference between a wavelength of the light emitted by the third light-emitting sub-layer 214c and a wavelength of the light emitted by the sixth light-emitting sub-layer 223c is less than or equal to 20 nm.

In an example, the absolute value of the difference between the wavelength of the light emitted by the first light-emitting sub-layer 214a and the wavelength of the light emitted by the fourth light-emitting sub-layer 223a is 5 nm, 10 nm, 15 nm or 20 nm.

In an example, the absolute value of the difference between the wavelength of the light emitted by the second light-emitting sub-layer 214b and the wavelength of the light emitted by the fifth light-emitting sub-layer 223b is 5 nm, 10 nm, 15 nm or 20 nm.

In an example, the absolute value of the difference between the wavelength of the light emitted by the third light-emitting sub-layer 214c and the wavelength of the light emitted by the sixth light-emitting sub-layer 223c is 5 nm, 10 nm, 15 nm or 20 nm.

According to the above embodiments, it can be known that by setting the absolute value of the difference between the wavelengths of the light emitted by the light-emitting sub-layers of the first light-emitting layer 214 to be less than or equal to 20 nm, and setting the absolute value of the difference between the wavelengths of the light emitted by the light-emitting sub-layers of the second light-emitting layer 223 to be less than or equal to 20 nm, the color separation caused by the microcavity effect can be prevented, and the color deviation problem is avoided.

In some embodiments, the first light-emitting sub-layer 214a, the second light-emitting sub-layer 214b and the third light-emitting sub-layer 214c independently emit light in any one of three colors including red, green and blue. In some embodiments, the fourth light-emitting sub-layer 223a, the fifth light-emitting sub-layer 223b and the sixth light-emitting sub-layer 223c independently emit light in any one of three colors including red, green and blue.

In an example, both the first light-emitting sub-layer 214a and the fourth light-emitting sub-layer 223a emit red light, both the second light-emitting sub-layer 214b and the fifth light-emitting sub-layer 223b emit green light, and both the third light-emitting sub-layer 214c and the sixth light-emitting sub-layer 223c emit blue light.

In some embodiments, the first charge generation layer 31 further includes an N-type dopant. The N-type dopant may be selected from any one of alkali metals and oxides thereof, alkaline earth metals and oxides thereof, transition metals and oxides thereof. A complex can be formed between the N-type dopant and the first type compound through a coordination bond, which can further improve the electron transport performance, thereby improving the luminous efficiency of the light-emitting device.

In an example, the N-type dopant is Yb (ytterbium).

It should be noted that alkali metals include all the metal elements in Group IA of the periodic table of elements, including lithium (Li), sodium (Na), potassium (K), rubidium (Rb), cesium (Cs) and francium (Fr). For example, Alkali metal oxides is lithium oxide, sodium oxide, or cesium oxide. The alkaline earth metals refer to the Group IIA elements in the periodic table of elements, including beryllium (Be), magnesium (Mg), calcium (Ca), strontium (Sr), barium (Ba), etc. The alkaline earth metal oxide is magnesium oxide or barium oxide, etc., which is not limited herein.

In some embodiments, the doping ratio of the N-type dopant in the first charge generation layer 31 ranges from 0.5% to 2%.

In an example, the doping ratio of the N-type dopant in the first charge generation layer 31 is 1%.

In some embodiments, any one of the first light-emitting sub-layer 214a, the second light-emitting sub-layer 214b, the third light-emitting sub-layer 214c, the fourth light-emitting sub-layer 223a, the fifth light-emitting sub-layer 223b and the sixth light-emitting sub-layer 223c includes: a first host material and a second host material.

The first host material and the second host material constitute the exciplex. The difference between a wavelength corresponding to a peak of the emission spectrum of the exciplex and a wavelength corresponding to a peak of the emission spectrum of the first host material is greater than or equal to 20 nm, and the difference between the wavelength corresponding to the peak of the emission spectrum of the exciplex and a wavelength corresponding to a peak of the emission spectrum of the second host material is greater than or equal to 20 nm. The molecular distance between the HOMO unit of the first host material and the LUMO unit of the second host material is greater than or equal to 3.4 Å and less than or equal to 5 Å.

According to the above embodiments, it can be seen that using an exciplex as the host material of the light-emitting layer in the present disclosure can control the balance of the carriers in the light-emitting layer better, effectively regulate the exciton recombination region, and increase the utilization rate of the excitons. Meanwhile, combined with the optimization of the CGL materials, the efficiency of the device can be further improved.

It should be noted that the material of the light-emitting layer includes a host material and a guest material. The host material includes: a p-type material and an n-type material, and an exciplex is formed between the p-type material and the n-type material. The molecular structures of both the p-type material and the n-type material include LUMO unit and HOMO unit. When the molecular distance (d) is 3.4 Å≤d≤5 Å, the LUMO unit in p-type material and the HOMO unit in n-type material disappear, and the HOMO unit in the p-type material and the LUMO unit in the n-type material are combined to form an exciplex.

In some embodiments, any one of the first light-emitting sub-layer 214a, the second light-emitting sub-layer 214b, the third light-emitting sub-layer 214c, the fourth light-emitting sub-layer 223a, the fifth light-emitting sub-layer 223b and the sixth light-emitting sub-layer 223c includes: a first host material and a second host material. The first host material and the second host material are the isomers or the homologues. An absolute value of a difference between the wavelength corresponding to the peak of the emission spectrum of the first host material and the wavelength corresponding to the peak of the emission spectrum of the second host material is less than 10 nm. Both the first host material and the second host material may be derivatives of anthracene.

It should be noted that the structures of the homolog of anthracene or the isomer of anthracene are similar, which may ensure that no exciplex causing a red shift in the spectrum may be formed between the homolog of anthracene and the isomer of anthracene, so that on the basis of maintaining the original properties of the material, the crystallization phenomenon of the material can be improved, thereby solving the problem of crucible clogging during mass production of materials. Meanwhile, two homologs of anthracene with similar structures or two isomers of anthracene with similar structures can directly obtain carriers from the adjacent functional layers without the energy transfer between each other, so there is no carrier trap formed due to the change of the concentration ratio, thereby avoiding the non-emitting phenomenon. In addition, a good amorphous film can be formed, thereby enhancing the performance of the device and increasing the service life of the device.

In some embodiments, the mass ratio between the first host material and the second host material is greater than or equal to 1/99 and less than or equal to 99.

In some embodiments, any one of the light-emitting sub-layers of the first light-emitting sub-layer 214a, the second light-emitting sub-layer 214b, the third light-emitting sub-layer 214c, the fourth light-emitting sub-layer 223a, the fifth light-emitting sub-layer 223b and the sixth light-emitting sub-layer 223c includes a host material and a guest material. The guest material is a phosphorescent dopant or a fluorescent dopant.

In some embodiments, the first light-emitting sub-layer 214a and the fourth light-emitting sub-layer 223a are red light-emitting layers, and the host material of the red light-emitting layer may be a DCM series material, such as DCM, DCJTB, DCJTI, etc., or the host material of the red light-emitting layer may be DCzDBT. The guest material may be a metal complex, such as Ir(piq)2(acac), PtOEP, Ir(btp)2(acac), etc. The formulas of DCzDBT and Ir(piq)2(acac) are as follows.

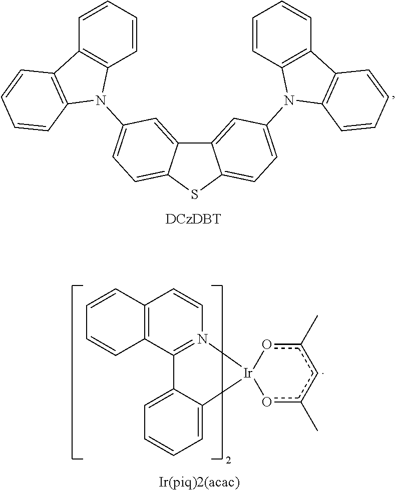

The second light-emitting sub-layer 214b and the fifth light-emitting sub-layer 223b are green light-emitting layers. The host material of the green light-emitting layer may be coumarin dyes, quinacridine copper derivatives, polycyclic aromatic hydrocarbons, and diamine anthracene derivatives, carbazole derivatives, such as DMQA, BA-NPB, Alq3, CBP, etc. The guest material may be a metal complex, such as Ir(ppy)3, Ir(ppy)2(acac), etc. The formulas of CBP and Ir(ppy)3 are as follows.

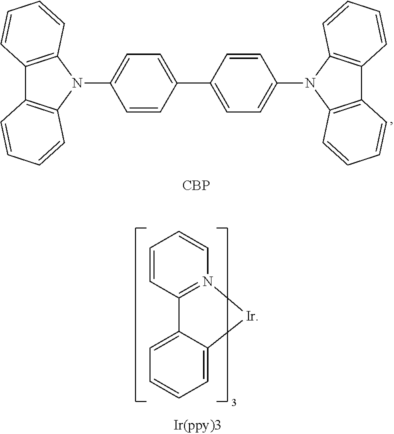

The third light-emitting sub-layer 214c and the sixth light-emitting sub-layer 223c are the blue light-emitting layers, and the host material of the blue light-emitting layer may be derivatives of anthracene, such as ADN, MADN, etc. The guest material may be pyrene derivatives, fluorene derivatives, perylene derivatives, styrylamine derivatives, metal complexes, etc., such as TBPe, BDAVBi, DPAVBi, FIrpic, etc. The formulas of ADN and DPAVBi are as follows.

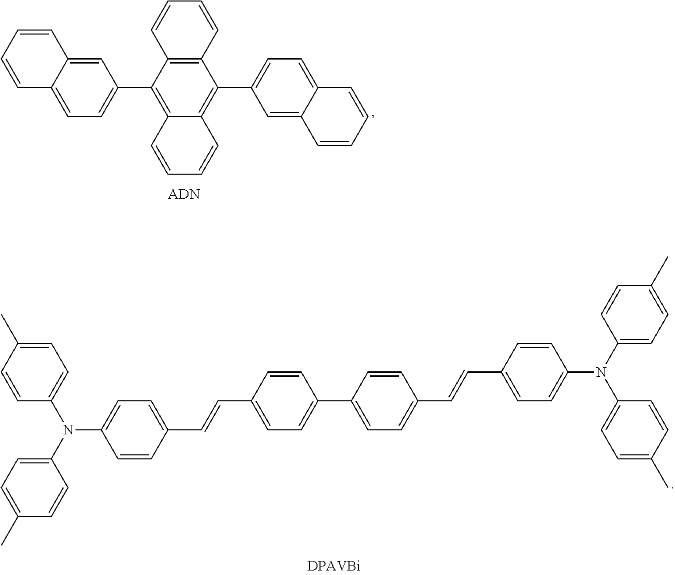

Based on the above description for the structures of the light-emitting devices, in the embodiments of the present disclosure, an embodiment for the structure of the light-emitting device is further provided.

As shown in FIG. 2, the light-emitting device includes: an anode 1, a hole injection layer 211 (5 to 30 nm), a first hole transport layer 212 (15 to 25 nm), and a first electron barrier layer 213 (5 to 15 nm), a first light-emitting layer 214 (10 to 20 nm), a first hole barrier layer 215 (5 to 15 nm), a first charge generation layer 31 (15-25 nm), a second charge generation layer 32 (5-15 nm), a second hole transport layer 221 (15 to 25 nm), a second electron barrier layer 222 (5 to 15 nm), a second light-emitting layer 223 (10 to 20 nm), a second hole barrier layer 224 (5 to 25 nm), an electron transport layer 225 (20 to 100 nm), an electron injection layer EIL (1 to 10 nm), and a cathode 4 (10 to 20 nm) which are arranged sequentially along a first direction.

It should be noted that the value in parentheses after the film layer refers to the thickness range of the film layer. For example, the hole injection layer 211 (5 to 30 nm) means that the thickness of the hole injection layer 211 ranges from 5 nm to 30 nm. The cathode 4 and the anode 1 are disposed oppositely, and the first direction is the direction from the anode 1 to the cathode 4.

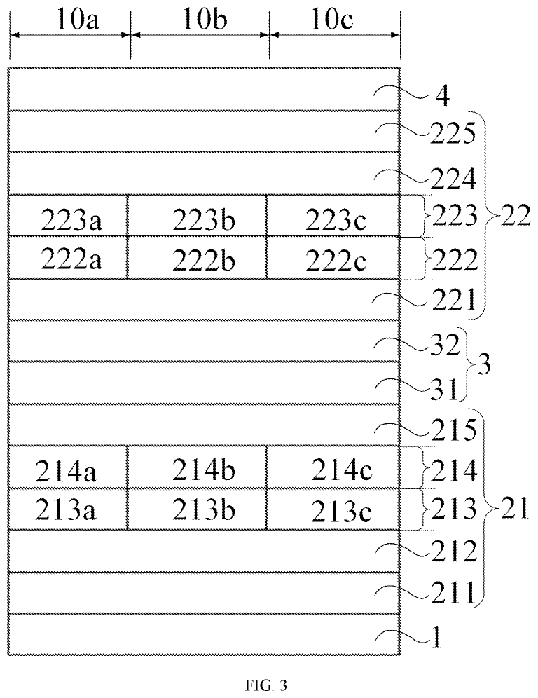

In an example, the anode 1 in the light-emitting device is made of ITO material. As shown in FIG. 3, the thickness of each film layer in the light-emitting device is as follows, the hole injection layer 211 (10 nm), the first hole transport layer 212 (19 nm), the first electron barrier layer 213 (the thickness of the first electron barrier sub-layer 213a is 25 nm, the thickness of the second electron barrier sub-layer 213b is 15 nm, and the thickness of the third electron barrier sub-layer 213c is 5 nm, where the first light-emitting region 10a emits red light, the second light-emitting region 10b emits green light, and the third light-emitting region 10c emits blur-light), the first light-emitting layer 214 (3 wt %, 15 nm), the first hole barrier layer 215 (5 nm), the first charge generation layer 31 (1 wt % Yb, 18 nm), the second charge generation layer 32 (5 wt %, 9 nm), the second hole transport layer 221 (19 nm), the second electron barrier layer 222 (the thickness of the fourth electron barrier sub-layer 222a is 25 nm, the thickness of the fifth electron barrier sub-layer 222b is 15 nm, the thickness of the six electron barrier sub-layer 222c is 5 nm, where the first light-emitting region 10a emits red light, the second light-emitting region 10b emits green light, and the third light-emitting region 10c emits blue light), the second light-emitting layer 223 (3 wt %, 15 nm), the second hole barrier layer 224 (5 nm), the electron transport layer 225 (50 wt % TPBi, 50 wt % LiQ, 35 nm), the electron injection layer EIL (1 nm), the cathode 4 (15 nm).

It should be noted that, in the first light-emitting layer 214 (3 wt %, 15 nm), 3 wt % means that the mass proportion of the guest material in the first light-emitting layer 214 is 3%, and 15 nm means that the thickness of the first light-emitting layer 214 is 15 nm. Similarly, in the first charge generation layer 31 (1 wt % Yb, 18 nm), 1 wt % Yb means that the mass proportion of the N-type dopant ytterbium (Yb) in the first charge generation layer 31 is 1%. In the second charge generation layer 32 (5 wt %, 9 nm), 5 wt % means that the mass proportion of the third type compound material in the second charge generation layer 32 is 5%. In the electron transport layer 225 (50 wt % TPBi, 50 wt % LiQ, 35 nm), 50 wt % TPBi means that the mass proportion of TPBi in the electron transport layer 225 is 50%, and 50 wt % LiQ means that the mass proportion of lithium octahydroxyquinolate (LiQ) in the electron transport layer 225 is 50%. The formulas of LiQ and TPBi are as follows.

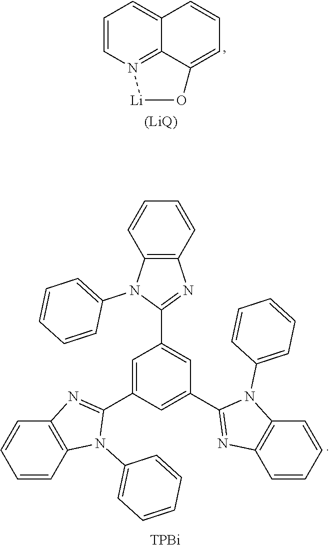

Based on the same inventive concept, according to the embodiments of the present disclosure, a method for manufacturing a light-emitting device is provided, which includes steps S1 to S4, specifically as follows.

S1: the first light-emitting unit 21 is formed on the substrate with an anode 1.

In some embodiments, the first light-emitting unit 21 includes the hole injection layer 211, the first hole transport layer 212, the first electron barrier layer 213, the first light-emitting layer 214 and the first hole barrier layer 215.

In some embodiments, before forming the first light-emitting unit 21 on the substrate with the anode 1, step S0 is further included. Step S0: the substrate with the anode 1 is cleaned.

In an example, the material of the anode 1 is indium tin oxide (ITO).

In an example, the material of the substrate is glass.

In an example, step S0 specifically includes: performing ultrasonic treatment of the glass substrate with ITO in a cleaning agent, rinsing in deionized water, ultrasonic degreasing in an acetone-ethanol mixed solvent, and baking in a clean environment until the moisture is completely removed.

S2: a charge generation layer 3 is formed at a side of the first light-emitting unit 21 away from the substrate.

In some embodiments, the charge generation layer 3 includes: a first charge generation layer 31 and a second charge generation layer 32 which are stacked sequentially along the first direction, where the first direction is a direction from the substrate to the first light-emitting unit 21.

In some embodiments, the first charge generation layer 31 includes the first type compound in the above embodiments. The second charge generation layer 32 includes the second type compound or the third type compound in the above embodiments.

S3: the second light-emitting unit 22 is formed on the side of the charge generation layer 3 away from the first light-emitting unit.

In some embodiments, the second light-emitting unit 22 includes: a second hole transport layer 221, a second electron barrier layer 222, a second light emitting layer 223, a second hole barrier layer 224 and an electron transport layer 225.

S4: the cathode 4 is formed on the side of the second light-emitting unit 22 away from the charge generation layer 3.

In an example, the cathode 4 is made of magnesium-silver alloy, and the mass ratio of magnesium (Mg) and silver (Ag) is 1:9.

In an example, an evaporation process is used to form the cathode 4.

In some embodiments, at step S1: forming the first light-emitting unit 21 on the substrate with the anode 1 specifically includes steps 101 to 105 as follows.

S101: the hole injection layer 211 is formed at the side of the anode 1 away from the substrate.

In an example, the glass substrate with the anode 1 is placed in a vacuum chamber and evacuated to 1×10⁻⁵ to 1×10⁻⁶, HATCN and NPB are co-evaporated in a vacuum on the side of the anode 1 away from the glass substrate, and the hole injection layer 211 is formed.

S102: the first hole transport layer 212 is formed on the side of the hole injection layer 211 away from the anode 1.

In an example, the material of the first hole transport layer 212 is NPB.

In an example, an evaporation process is used to form the first hole transport layer 212.

S103: the first electron barrier layer 213 is formed on the side of the first hole transport layer 212 away from the hole injection layer 211.

In an example, the formula of the material of the first electron barrier layer 213 is

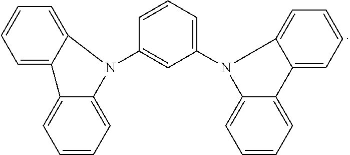 [SMILES: c1cc(-n2c3ccccc3c3ccccc32)cc(-n2c3ccccc3c3ccccc32)c1]

S104: the first light-emitting layer 214 is formed on the side of the first electron barrier layer 213 away from the first hole transport layer 212.

In an example, the first light-emitting layer 214 is composed of a host material and a guest material, and the mass proportion of the guest material in the first light-emitting layer 214 is 3%.

In an example, the first light-emitting layer 214 is formed using the evaporation process.

S105: the first hole barrier layer 215 is formed on the side of the first light-emitting layer 214 away from the first electron barrier layer 213.

In an example, the first hole barrier layer 215 is formed using the vacuum evaporation process.

In some embodiments, at step S2, forming the charge generation layer 3 on the side of the first light-emitting unit 21 away from the substrate specifically includes steps 201 to 202 as follows.

S201: the first charge generation layer 31 is formed on the side of the first hole barrier layer 215 away from the first light-emitting layer 214.

In an example, the first charge generation layer 31 includes 99 wt % of the first type compound and 1 wt % of metal ytterbium (Yb).

S202: the second charge generation layer 32 is formed on the side of the first charge generation layer 31 away from the first hole barrier layer 215.

In an example, the P-type charge layer includes 95 wt % of the second type compound and 5 wt % of the third type compound.

In some embodiments, at step S3: forming the second light-emitting unit 22 at the side of the charge generation layer 3 away from the first light-emitting unit specifically includes steps 301 to 305 as follows.

S301: the second hole transport layer 221 is formed on the side of the first charge generation layer 32 away from the first hole barrier layer 31.

In an example, the material of the second hole transport layer 221 is NPB.

In an example, the second hole transport layer 221 is formed using the evaporation process.

S302: the second electron barrier layer 222 is formed on the side of the second hole transport layer 221 away from the second charge generation layer 32.

In an example, the formula of the material of the second electron barrier layer 222 is

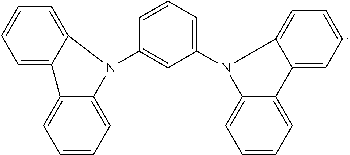 [SMILES: c1cc(-n2c3ccccc3c3ccccc32)cc(-n2c3ccccc3c3ccccc32)c1]

S303: the second light-emitting layer 223 is formed on the side of the second electron barrier layer 222 away from the second hole transport layer 221.

In an example, the second light-emitting layer 223 is composed of the host material and the guest material, and the mass proportion of the guest material in the second light-emitting layer 223 is 3%.

S304: the second hole barrier layer 224 is formed on the side of the second light-emitting layer 223 away from the second electron barrier layer 222.

In an example, the second hole barrier layer 224 is formed using the vacuum evaporation process.

S305: the electron transport layer 225 is formed on the side of the second hole barrier layer 224 away from the second light-emitting layer 223.

In an example, the material of the electron transport layer 225 is composed of the mixture of TPBi with the mass ratio of 50% and LiQ (lithium octahydroxyquinoline) with the mass ratio of 50%. The formulas of LiQ and TPBi are as follows.

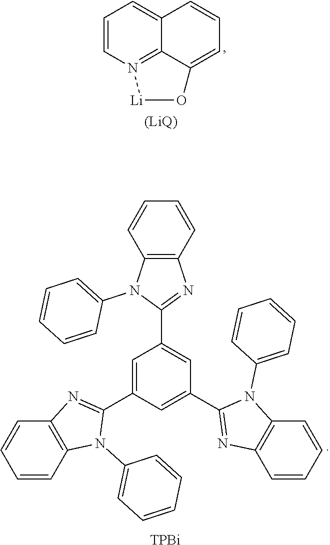

It should be noted that the materials of the film layers with the same function in the first light-emitting layer 214 and the second light-emitting layer 223 in the embodiments of the present disclosure may be the same or different, which is not limited herein.

In order to further demonstrate that the provided light-emitting devices according to the embodiments of the present disclosure have better luminous efficiency and service life. In the present disclosure, the following embodiments 1 to 3 and comparative examples 1 to 3 are further provided for comparison. The light-emitting devices are tested under the same test environment, and the structures and the materials of the film layers except the charge generation layer 3 are the same. In N-CGL, the doping proportion of Yb is 1 wt %, and the proportion of the remaining formula (1-1) or formula (1-2) or formula (1-3) or comparative N-CGL is 99 wt %. In P-CGL, the doping ratio of formula (3-1) or P—W is 1 wt %, and the ratio of the remaining formula (2-1) or formula (2-10) or comparative P-CGL is 98 wt %. The types of the first charge generation layer 31 (N-CGL) and the second charge generation layer 32 (P-CGL) are specifically shown in Table 2. The formulas of comparative N-CGL, P—W and comparative P-CGL are as follows.

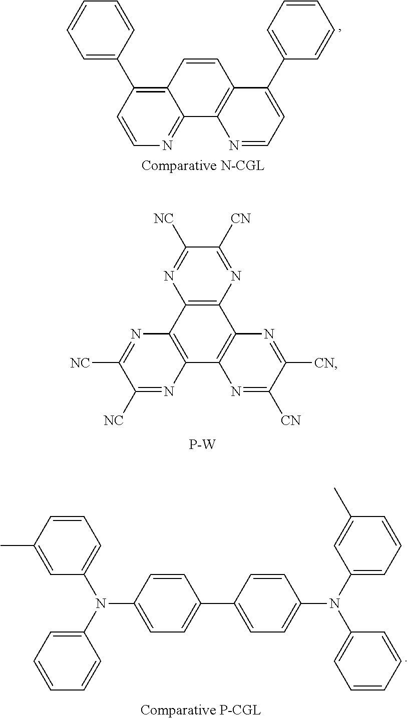 [SMILES: c1ccc(-c2ccnc3c2ccc2c(-c4ccccc4)ccnc23)cc1 ; N#Cc1nc2c3nc(C#N)c(C#N)nc3c3nc(C#N)c(C#N)nc3c2nc1C#N ; "P-W" ; Cc1cccc(N(c2ccccc2)c2ccc(-c3ccc(N(c4ccccc4)c4cccc(C)c4)cc3)cc2)c1]

It should be noted that the formulas (1-1), (1-2), (1-3), (2-1), (2-10) and (3-1) can be found in the contents of the aforementioned embodiments and will not be described again here.

TABLE 2
Material types of the first charge generation layer 31 (N-
CGL) and the second charge generation layer 32 (P-CGL) used
in embodiment 1 to 3 and comparative examples 1 to 3

| | N-CGL | P-CGL |
|---|---|---|
| Embodiment 1 | (1-1):Yb | (2-1):(3-1) |
| Embodiment 2 | (1-2):Yb | (2-10):(3-1) |
| Embodiment 3 | (1-3):Yb | (2-1):(3-1) |
| Comparative example 1 | (1-3):Yb | Comparative |
| | | P-CGL:P-W |
| Comparative example 2 | Comparative | (2-1):(3-1) |
| | N-CGL:Yb | |
| Comparative example 3 | Comparative | Comparative |
| | N-CGL:Yb | P-CGL:P-W |

The driving voltage V), luminous efficiency cdA and service life (h) the light-emitting devices formed in the embodiments 1 to 3 and the comparative examples 1 to 3 are measured at a fixed current density (@15 mA/cm²), where the color coordinate condition of the emitted light is: CIEx=0.25, CIEy=0.72, that is, the light-emitting device emits green light. The measurement results of the light emitted by the light-emitting unit 2 are shown in Table 3.

TABLE 3
Drive voltage, luminous efficiency and service life of the light-emitting
devices of embodiments 1 to 3 and comparative examples 1 to 3

| | Drive voltage | Luminous efficiency | Service life |
|---|---|---|---|
| Embodiment 1 | 94.23% | 132.46% | 139.81% |
| Embodiment 2 | 93.72% | 135.89% | 135.58% |
| Embodiment 3 | 95.65% | 138.11% | 129.49% |
| Comparative | 100.11% | 101.22% | 101.89% |
| example 1 | | | |
| Comparative | 99.03% | 100.98% | 100.71% |
| example 2 | | | |
| Comparative | 100% | 100% | 100% |
| example 3 | | | |

As can be seen from Table 3, by taking the measurement results in comparative example 3 as reference, the driving voltage, the luminous efficiency and the service life of the comparative example 3 are all set to 100%. In comparative example 1 or comparative example 2, the materials of the present disclosure are only used in the N-type charge generation layer or the P-type charge generation layer without combining the two materials in the present disclosure. Therefore, the luminous efficiency and service life are not improved significantly. Compared with the comparative examples 1 to 3, in embodiments 1 to 3, N-CGL and P-CGL provided by the present disclosure are used together, and the luminous efficiency and service life are significantly improved. Specifically, the luminous efficiency and the service life are increased by about 30%. Therefore, it is further verified that when the N-CGL and P-CGL provided by the present disclosure are used together, the luminous efficiency and service life of the light-emitting device can be significantly improved, thereby improving the optoelectronic performance of the light-emitting device.

Based on the same inventive concept, the embodiments of the present disclosure provide a display panel, including the light-emitting device provided in the above embodiments. Therefore, the display panel has all the features and the advantages of the aforementioned light-emitting device, which will not be described again herein.

In some embodiments, the display panel further includes a substrate, which is disposed at a side of the anode 1 away from the first light-emitting unit 21. The substrate can be any transparent rigid or flexible substrate material, such as glass, polyimide (PI), etc.

According to the present disclosure, a display apparatus including the display panel described above is provided. Therefore, the display apparatus has all the features and advantages of the aforementioned display panel, which will not be described again herein.

It should be noted that the display apparatus may be any devices that displays images, whether movable (e.g., video) or fixed (e.g., still images), and whether text or image. More particularly, it is contemplated that the embodiments may be implemented in or associated with a variety of electronic devices such as, but not limited to, mobile telephones, wireless devices, personal data assistant (PDA), hand-held or portable computers, GPS receivers/navigators, cameras, MP4 players, camcorders, game consoles, wrist watches, clocks, calculators, television monitors, flat panel displays, computer monitors, auto displays (e.g., odometer display, etc.), cockpit controls and/or displays, display of camera views (e.g., display of a rear view camera in a vehicle), electronic photographs, electronic billboards or signs, projectors, architectural structures, packaging, and aesthetic structures (e.g., image displays for a piece of jewelry).

The above-mentioned embodiments of the present disclosure can complement each other without conflict.

It should be noted that in the accompanying drawings, the dimensions of the layers and the regions may be exaggerated for clarity of illustration. It will also be understood that when an element or a layer is referred to as being “on” another element or another layer, it can be directly on the other element, or intermediate layer may be present. In addition, it will be understood that when an element or a layer is referred to as being “under” another element or another layer, it can be directly under the other element, or one or more intermediate layer or element may be present. In addition, it will also be understood that when an element or a layer is referred to as being “between” two elements or two layers, it can be an only layer, or one or more intermediate layer or element may be present. Similar reference numbers indicate similar elements throughout.

It should be understood that the terms “center”, “upper”, “lower”, “front”, “rear”, “left”, “right”, “vertical”, “horizontal”, “top”, “bottom”, “inner”, “outer”, and the like indicate the orientation or position relationship based on the orientation or position relationship shown in the drawings, are merely for the convenience of describing the present invention and simplifying the description, and do not indicate or imply that the referred device or component must have a specific orientation, be constructed and operated in a specific orientation, and therefore cannot be understood as a limitation on the present disclosure.

In addition, the terms “first” and “second” are used for description purposes only, and cannot be understood as indicating or implying relative importance or implicitly indicating the number of technical features indicated. Thus, features defining “first” and “second” may explicitly or implicitly include one or more of the features. In the description of the present disclosure, “a plurality of” means two or more, unless specifically defined otherwise.

Other embodiments of the present disclosure will be readily apparent to those skilled in the art upon consideration of this description and practicing the disclosure disclosed herein. The present disclosure is intended to cover any variations, uses, or adaptations of the present disclosure which follow the general principles of the present disclosure and include common knowledge or customary technical means in this technical field that are not disclosed in the present disclosure. It is intended that the specification and embodiments are considered as exemplary only, and the true scope and the spirit of the present disclosure is indicated by the following claims.

It is to be understood that the present disclosure is not limited to the precise structures described above and illustrated in the accompanying drawings, and that various modifications and changes may be made without departing from the scope thereof. The scope of the present disclosure is limited only by the appended claims.

1. A device, comprising:
a light-emitting unit comprising a first light-emitting unit and a second light-emitting unit stacked along a first direction;
an anode and a cathode at opposite sides of the light-emitting unit;
a charge generation layer between the first light-emitting unit and the second light-emitting unit and comprising a first charge generation layer and a second charge generation layer stacked along the first direction;
wherein the first charge generation layer comprises a first type compound, and the second charge generation layer comprises a second type compound and a third type compound;
wherein the first direction is from the anode to the cathode;
wherein the first type compound has a structure shown in formula (I): 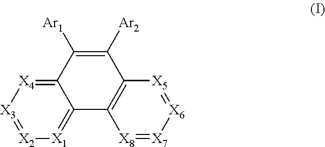
wherein each of groups X₁ to X₈ is independently selected from a group consisting of a nitrogen atom and R₁, and the groups X₁ to X₈ collectively comprise at least two nitrogen atoms;
wherein R₁ is selected from a group consisting of hydrogen, deuterium, substituted C₁ to C₆₀ alkyl group, unsubstituted C₁ to C₆₀ alkyl group, substituted C₂ to C₆₀ alkenyl group, unsubstituted C₂ to C₆₀ alkenyl group, substituted C₂ to C₆₀ alkynyl group, unsubstituted C₂ to C₆₀ alkynyl group, substituted C₁ to C₆₀ alkoxy group, unsubstituted C₁ to C₆₀ alkoxy group, substituted C₃ to C₁₀ ring alkyl, unsubstituted C₃ to C₁₀ ring alkyl, substituted C₁ to C₁₀ heterocycloalkyl, unsubstituted C₁ to C₁₀ heterocycloalkyl, substituted C₃ to C₁₀ cycloalkenyl, unsubstituted C₃ to C₁₀ cycloalkenyl, substituted C₁ to C₁₀ heterocycloalkenyl, unsubstituted C₁ to C₁₀ heterocycloalkenyl, substituted C₆ to C₆₀ aryl group, unsubstituted C₆ to C₆₀ aryl group, substituted C₆ to C₆₀ aryloxy group, unsubstituted C₆ to C₆₀ aryloxy group, substituted C₆ to C₆₀ arylthio group, unsubstituted C₆ to C₆₀ arylthio group, substituted C₁ to C₆₀ heteroaryl group, unsubstituted C₁ to C₆₀ heteroaryl group, substituted monovalent non-aromatic condensed polycyclic group, unsubstituted monovalent non-aromatic condensed polycyclic group, substituted monovalent non-aromatic condensed heteropolycyclic group and unsubstituted monovalent non-aromatic condensed heteropolycyclic group; and
wherein each of groups Ar₁ and Ar₂ is independently selected from a group consisting of: hydrogen, deuterium, tritium, halogen, cyano, nitro, C₆ to C₆₀ aryl, C₂ to C₆₀ heterocyclic group containing at least one heteroatom from O, N, S, Si and P, C₃ to C₆₀ aliphatic ring, C₆ to C₆₀ aromatic ring fused ring group, C₁ to C₅₀ alkyl group, C₂ to C₂₀ alkenyl group, C₂ to C₂₀ alkynyl group, C₁ to C₃₀ alkoxy group, C₆ to C₃₀ aryloxy group, C₃ to C₆₀ alkylsilyl group, C₁₈ to C₆₀ arylsilyl group and C₈ to C₆₀ alkylarylsilyl group;
wherein the second type compound has a structure shown in formula (II): 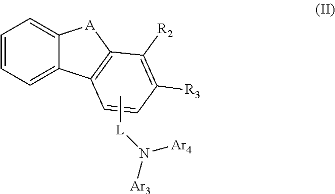
wherein A indicates O, S, C, N, or Si;
wherein L indicates a direct bond, and selected from a group consisting of: substituted phenyl group, unsubstituted phenyl group, substituted biphenyl, unsubstituted biphenyl, substituted terphenyl, unsubstituted terphenyl, substituted fluorenyl, unsubstituted fluorenyl, substituted adamantane group, unsubstituted adamantane group, substituted heteroaryl group, unsubstituted heteroaryl group;
wherein substitution conditions of R₂ and R₃ are same as a substitution condition of R₁;
wherein each of groups Ar₃ and Ar₄ is independently selected from a group consisting of: substituted phenyl group, unsubstituted phenyl group, substituted biphenyl group, unsubstituted biphenyl group, substituted naphthalene, unsubstituted naphthalene, substituted dibenzofuran, unsubstituted dibenzofuran, substituted carbazole, unsubstituted carbazole, substituted of fluorenyl group and unsubstituted of fluorenyl group; and
wherein the third type compound has a structure shown in formula (III): 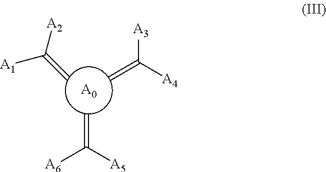
wherein each of A₁ to A₆ is independently selected from a group consisting of: substituted or unsubstituted halogen, unsubstituted halogen, substituted or unsubstituted cyano group, unsubstituted cyano group, substituted or unsubstituted aldehyde group, unsubstituted aldehyde group, substituted or unsubstituted carbonyl group, unsubstituted carbonyl group, substituted or unsubstituted carboxyl group, unsubstituted carboxyl group, substituted or unsubstituted sulfonic acid group, unsubstituted sulfonic acid group, substituted or unsubstituted nitro group, unsubstituted nitro group, aryl group substituted by an electron-withdrawing group, and heteroaryl substituted by an electron-withdrawing group; and
wherein A₀ is a three-membered ring, a four-membered ring, a five-membered ring, or a six-membered ring.

2. The device according to claim 1, wherein the first type compound has a structure shown in any one of following formulas:

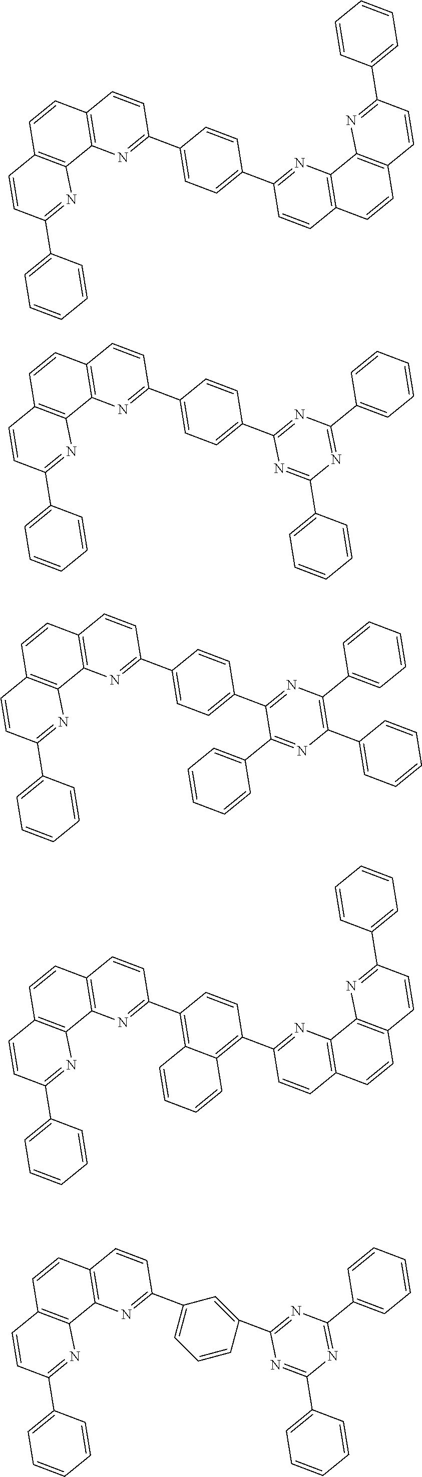

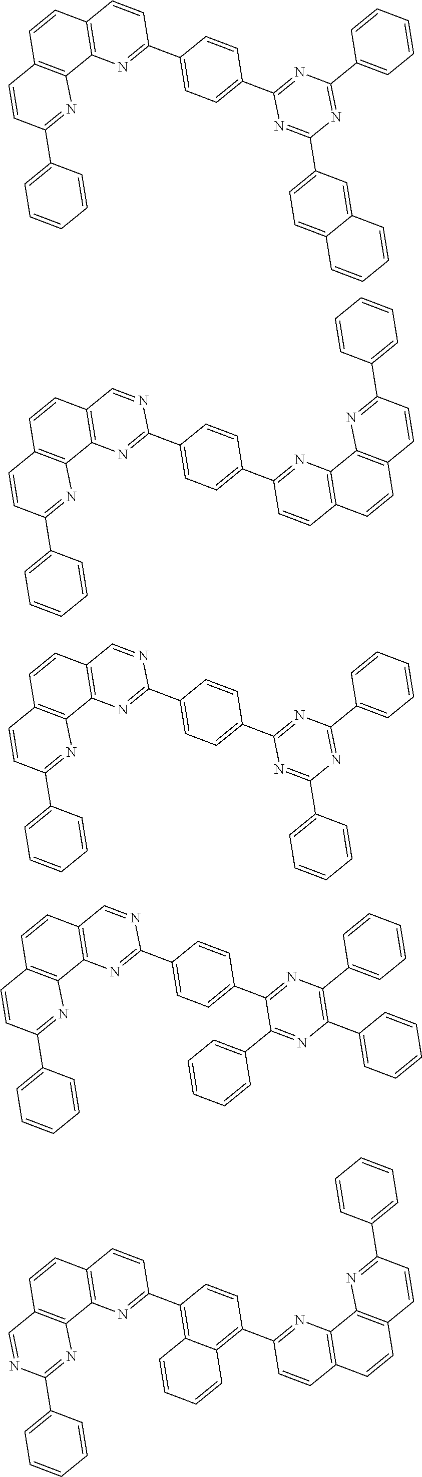

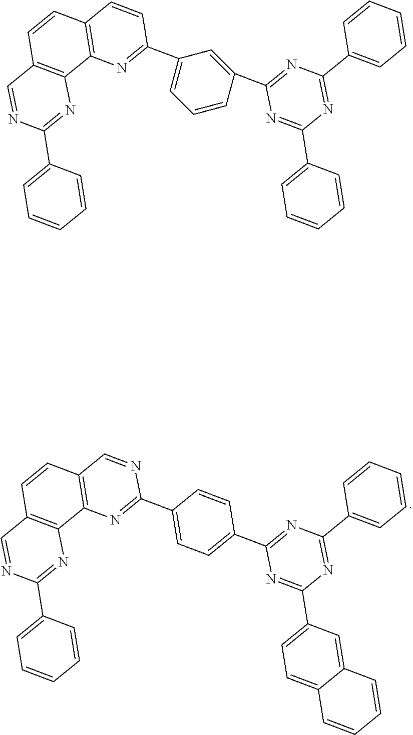 [SMILES: c1ccc(-c2nc(-c3ccccc3)nc(-c3cccc(-c4ccc5ccc6cnc(-c7ccccc7)nc6c5n4)c3)n2)cc1 ; c1ccc(-c2nc(-c3ccc(-c4ncc5ccc6cnc(-c7ccccc7)nc6c5n4)cc3)nc(-c3ccc4ccccc4c3)n2)cc1]

3. The device according to claim 1, wherein the second type compound has a structure shown in any one of following formulas:

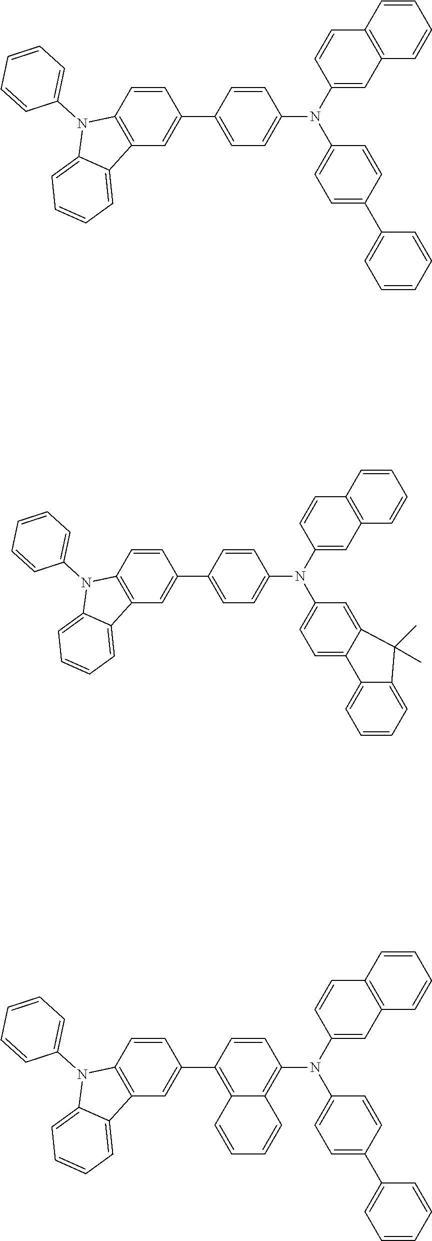 [SMILES: c1ccc(-c2ccc(N(c3ccc(-c4ccc5c(c4)c4ccccc4n5-c4ccccc4)cc3)c3ccc4ccccc4c3)cc2)cc1 ; CC1(C)c2ccccc2-c2ccc(N(c3ccc(-c4ccc5c(c4)c4ccccc4n5-c4ccccc4)cc3)c3ccc4ccccc4c3)cc21 ; c1ccc(-c2ccc(N(c3ccc4ccccc4c3)c3ccc(-c4ccc5c(c4)c4ccccc4n5-c4ccccc4)c4ccccc34)cc2)cc1]

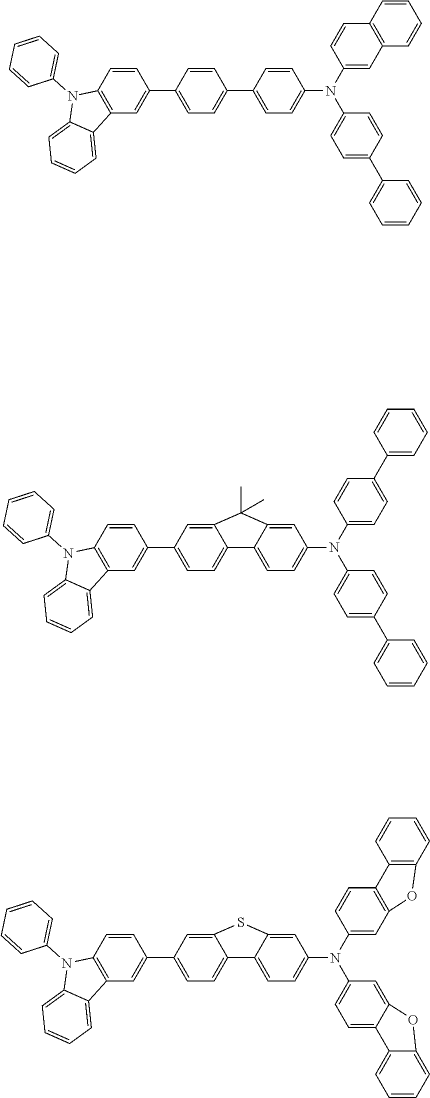 [SMILES: c1ccc(-c2ccc(N(c3ccc(-c4ccc(-c5ccc6c(c5)c5ccccc5n6-c5ccccc5)cc4)cc3)c3ccc4ccccc4c3)cc2)cc1 ; CC1(C)c2cc(-c3ccc4c(c3)c3ccccc3n4-c3ccccc3)ccc2-c2ccc(N(c3ccc(-c4ccccc4)cc3)c3ccc(-c4ccccc4)cc3)cc21 ; c1ccc(-n2c3ccccc3c3cc(-c4ccc5c(c4)sc4cc(N(c6ccc7c(c6)oc6ccccc67)c6ccc7c(c6)oc6ccccc67)ccc45)ccc32)cc1]

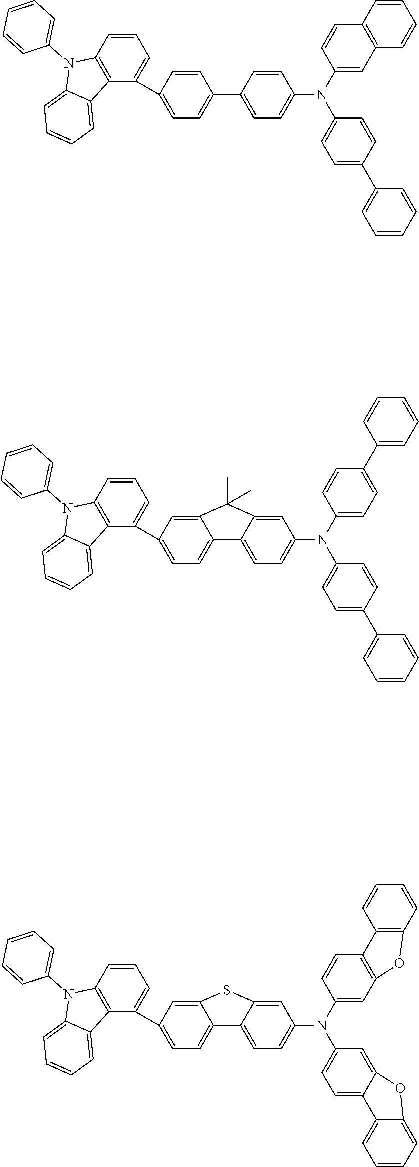 [SMILES: c1ccc(-c2ccc(N(c3ccc(-c4ccc(-c5cccc6c5c5ccccc5n6-c5ccccc5)cc4)cc3)c3ccc4ccccc4c3)cc2)cc1 ; CC1(C)c2cc(-c3cccc4c3c3ccccc3n4-c3ccccc3)ccc2-c2ccc(N(c3ccc(-c4ccccc4)cc3)c3ccc(-c4ccccc4)cc3)cc21 ; c1ccc(-n2c3ccccc3c3c(-c4ccc5c(c4)sc4cc(N(c6ccc7c(c6)oc6ccccc67)c6ccc7c(c6)oc6ccccc67)ccc45)cccc32)cc1]

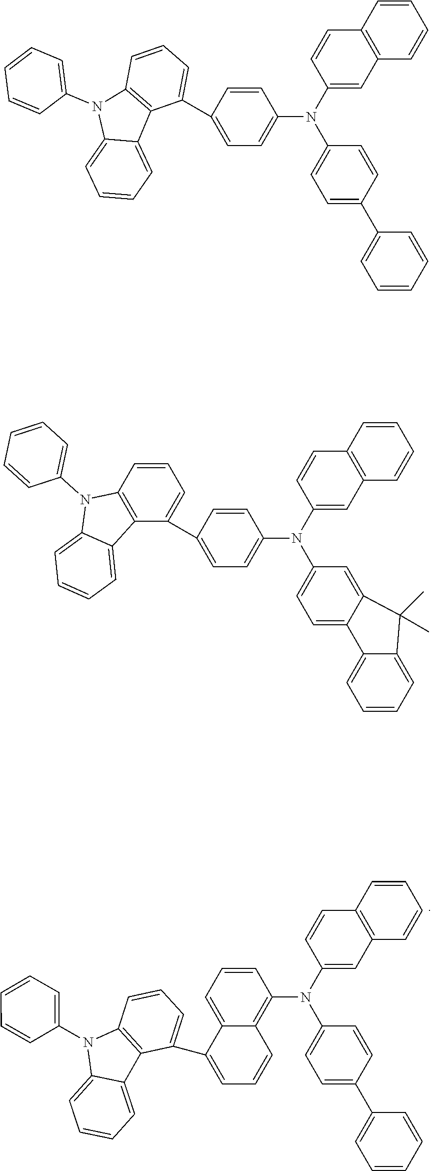 [SMILES: c1ccc(-c2ccc(N(c3ccc(-c4cccc5c4c4ccccc4n5-c4ccccc4)cc3)c3ccc4ccccc4c3)cc2)cc1 ; CC1(C)c2ccccc2-c2ccc(N(c3ccc(-c4cccc5c4c4ccccc4n5-c4ccccc4)cc3)c3ccc4ccccc4c3)cc21 ; c1ccc(-c2ccc(N(c3ccc4ccccc4c3)c3cccc4c(-c5cccc6c5c5ccccc5n6-c5ccccc5)cccc34)cc2)cc1]

4. The device according to claim 1, wherein the third type compound has a structure shown in any one of following formulas:

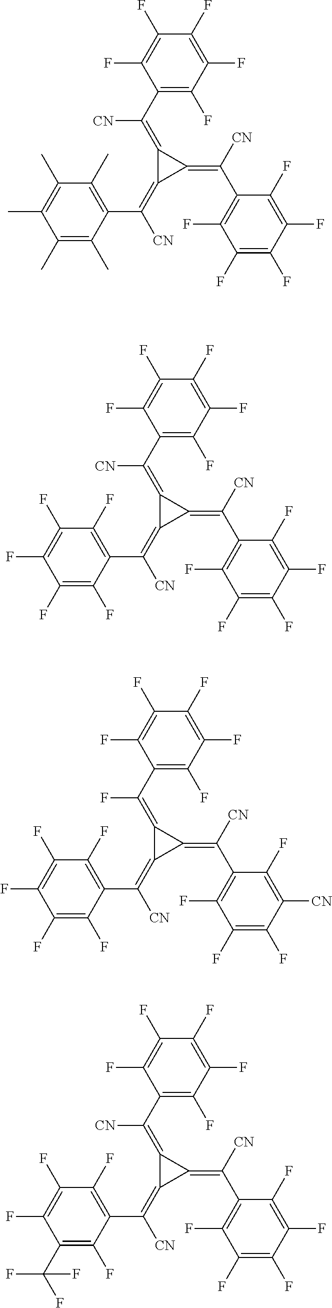

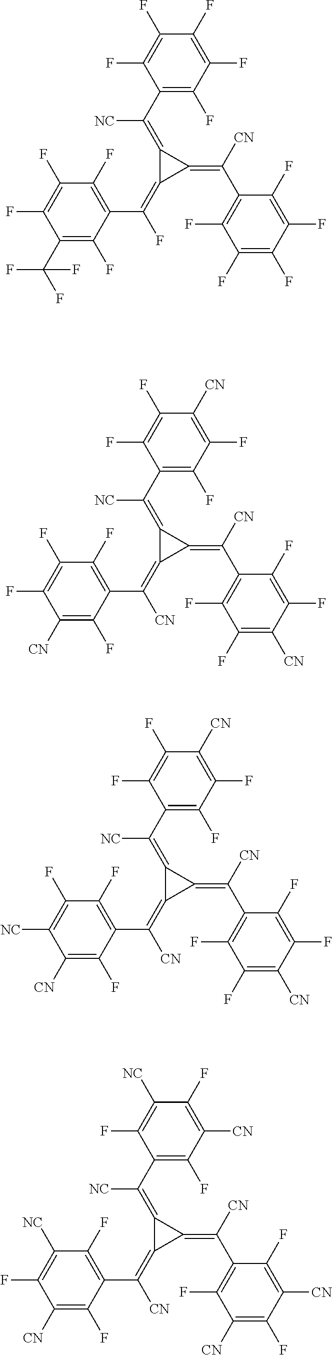

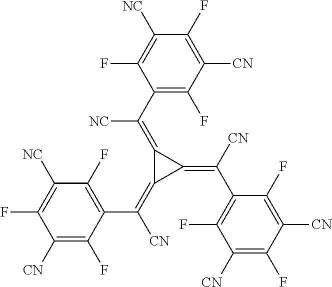

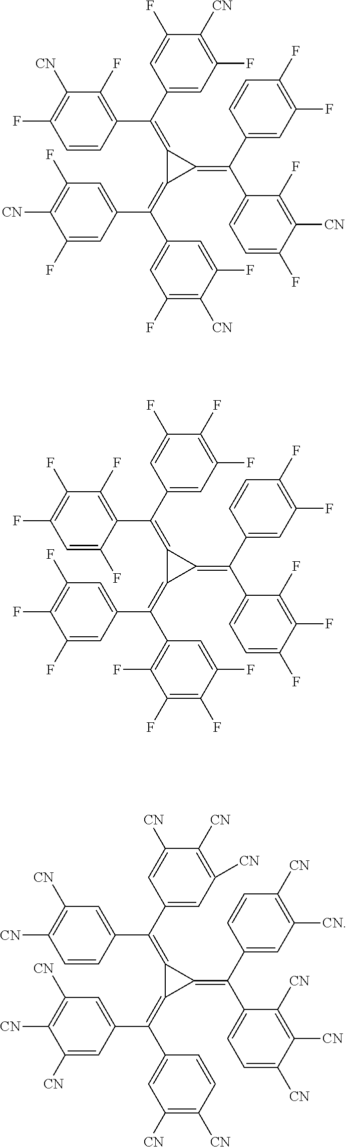

5. The device according to claim 1, wherein the first light-emitting unit comprises: a hole injection layer, a first hole transport layer, a first electron barrier layer, a first light-emitting layer and a first hole barrier layer that are stacked sequentially along the first direction; and
wherein an absolute value of a difference between a Lowest Unoccupied Molecular Orbital (LUMO) energy level of the first charge generation layer and a LUMO energy level of the first hole barrier layer is less than or equal to 0.5 eV.

6. The device according to claim 5, wherein the second light-emitting unit comprises: a second hole transport layer, a second electron barrier layer, and a second light-emitting layer, a second hole barrier layer and an electron transport layer that are stacked sequentially along the first direction; and
wherein an absolute value of a difference between a Highest Occupied Molecular Orbital (HOMO) energy level of the second charge generation layer and a HOMO energy level of the second hole transport layer is less than or equal to 0.3 eV.

7. The device according to claim 1, wherein a dipole moment of the charge generation layer is greater than 4·10⁻¹⁸ esu·cm.

8. The device according to claim 5, wherein an electron mobility of the first charge generation layer is greater than an electron mobility of the first hole barrier layer.

9. The device according to claim 6, wherein a hole mobility of the second charge generation layer is greater than a hole mobility of the second hole transport layer.

10. The device according to claim 6, wherein a ratio between the electron mobility of the first hole barrier layer and an electron mobility of the second hole barrier layer is greater than or equal to 0.1 and less than or equal to 10.

11. The device according to claim 6, wherein the first light-emitting layer comprises a first light-emitting sub-layer, a second light-emitting sub-layer and a third light-emitting sub-layer that are arranged sequentially along a second direction; and
wherein the second light-emitting layer comprises a fourth light-emitting sub-layer, a fifth light-emitting sub-layer and a sixth light-emitting sub-layer which are arranged sequentially along the second direction, wherein the second direction is perpendicular to the first direction;
wherein an absolute value of a difference between a wavelength of light emitted by the first light-emitting sub-layer and a wavelength of light emitted by the fourth light-emitting sub-layer is less than or equal to 20 nm;
wherein an absolute value of a difference between a wavelength of light emitted by the second light-emitting sub-layer and a wavelength of light emitted by the fifth light-emitting sub-layer is less than or equal to 20 nm; and/or
wherein an absolute value of a difference between a wavelength of light emitted by the third light-emitting sub-layer and a wavelength of light emitted by the-sixth light-emitting sub-layer is less than or equal to 20 nm.

12. The device according to claim 11, wherein the first light-emitting sub-layer, the second light-emitting sub-layer and the third light-emitting sub-layer independently emit light selected from a group consisting of red light, green light and blue light; and
the fourth light-emitting sub-layer, the fifth light-emitting sub-layer and the sixth light-emitting sub-layer independently emit light selected from a group consisting of red light, green light and blue light.

13. The device according to claim 1, wherein the first charge generation layer further comprises an N-type dopant selected from a group consisting of alkali metals, oxides of alkali metals, alkaline earth metals, oxides of alkaline earth metals, transition metals and oxides of transition metals.

14. The device according to claim 11, wherein any one of the first light-emitting sub-layer, the second light-emitting sub-layer, the third light-emitting sub-layer, the fourth light-emitting sub-layer, the fifth light-emitting sub-layer and the sixth sub-light-emitting comprises: a first host material and a second host material;
wherein the first host material and the second host material compose an exciplex, a difference between a wavelength corresponding to a peak of an emission spectrum of the exciplex and a wavelength corresponding to a peak of an emission spectrum of the first host material is greater than or equal to 20 nm, and a difference between the wavelength corresponding to the peak of the emission spectrum of the exciplex and a wavelength corresponding to a peak of an emission spectrum of the second host material is greater than or equal to 20 nm; and
wherein a molecular distance between a HOMO unit of the first host material and a LUMO unit of the second host material is higher than or equal to 3.4 Å and less than or equal to 5 Å.

15. The device according to claim 11, wherein any one of the first light-emitting sub-layer, the second light-emitting sub-layer, the third light-emitting sub-layer, the fourth light-emitting sub-layer, the fifth light-emitting sub-layer and the sixth light-emitting sub-layer comprises: a first host material and a second host material;
wherein the first host material and the second host material are isomers or homologues;
wherein an absolute value of a difference between a wavelength corresponding to a peak of an emission spectrum of the first host material and a wavelength corresponding to a peak of an emission spectrum of the second host material is less than 10 nm; and
wherein both the first host material and the second host material are derivatives of anthracene.

16. The device according to claim 14, wherein a mass ratio between the first host material and the second host material is greater than or equal to 1/99 and less than or equal to 99.

17. A display panel, comprising:
the light-emitting device according to claim 1.

18. A display apparatus, comprising the display panel according to claim 17.

19. The device according to claim 6, wherein a ratio between a hole mobility of the first hole transport layer and a hole mobility of the second hole transport layer is greater than or equal to 0.1 and less than or equal to 10.

20. The device according to claim 15, wherein a mass ratio between the first host material and the second host material is greater than or equal to 1/99 and less than or equal to 99.
